(19) United States
(12) Patent Application Publication
(10) Pub. No.: US 2021/0265189 A1
(43) Pub. Date: Aug. 26, 2021

(54) CERAMIC STRUCTURE AND WAFER SYSTEM

(71) Applicant: KYOCERA Corporation, Kyoto-shi, Kyoto (JP)

(72) Inventors: Yasunori KAWANABE, Kirishima-shi, Kagoshima (JP); Yoshihiro OKAWA, Kirishima-shi, Kagoshima (JP)

(21) Appl. No.: 17/277,235

(22) PCT Filed: Sep. 25, 2019
(86) PCT No.: PCT/JP2019/037531

§ 371 Date: Mar. 17, 2021

(30) Foreign Application Priority Data
Sep. 28, 2018 (JP) 2018-183970

(51) Int. Cl. H01L 21/683; H01L 23/34; H01L 23/40; H05B 3/28; H05B 3/26

(52) U.S. Cl. CPC H01L 21/683; H01L 23/345; H05B 3/265; H05B 3/28; H01L 23/40

(57) ABSTRACT

A heater includes a base body, a resistance heating element, and a terminal part. The base body is made of ceramic and is plate shaped including an upper surface on which a wafer is superimposed and a lower surface on an opposite side to the upper surface. The resistance heating element is located inside the base body. The terminal part is electrically connected to the resistance heating element, is at least partially located inside the base body, and is exposed from, the lower surface of the base body to an exterior of the base body. The lower surface of the base body includes an adjacent region which surrounds the terminal part. The adjacent region includes an inclined surface in a portion reaching the terminal part.

### TECHNICAL FIELD

The present disclosure relates to a ceramic structure and a wafer system including the ceramic structure.

### BACKGROUND ART

Known in the art is a ceramic structure on the upper surface of which a wafer is superimposed (for example PTL 1 or 2). Such a ceramic structure has a plate-shaped base body made of ceramic and an internal conductor positioned in an internal portion of the base body. Further, by application of voltage to the infernal conductor, the ceramic structure, for example, exerts a function of heating the wafer, a function of picking the wafer by suction, a function of generating plasma around the wafer, or a combination of two or more of these functions. Such a ceramic structure is for example used in a semiconductor manufacturing apparatus.

Patent Literatures 1 and 2 disclose ceramic heaters provided with resistance heating elements as internal conductors inside base bodies made of ceramic. Such ceramic heaters have terminals which are electrically connected with the internal conductors and are exposed from the lower surfaces of the base bodies. The lower surfaces of the base bodies are shaped as flat surfaces. Further, the lower surfaces of the terminals become flush with the lower surfaces of the base bodies.

### CITATION LIST

### Patent Literature

Patent Literature 1: Japanese Patent Publication No. 2004-87392

Patent Literature 2: Japanese Patent Publication No. 5-101871

### SUMMARY OF INVENTION

### Solution to Problem

A ceramic structure according to one aspect of the present disclosure includes a base body, an internal conductor, and a terminal part. The base body is made of ceramic and is plate shaped including an upper surface on which a wafer is superimposed and a lower surface on an opposite side to the upper surface. The internal conductor is located inside the base body. The terminal part is electrically connected to the internal conductor, is at least partially located inside the base body, and is exposed from the lower surface of the base body to an exterior of the base body. The lower surface of the base body includes an adjacent region which surrounds the terminal part. The adjacent region includes an inclined surface in a portion reaching the terminal part.

A wafer system according to one aspect of the present disclosure includes the ceramic structure described above, a power supply part which supplies power to the terminal part, and a control part which controls the power supply part.

### BRIEF DESCRIPTION OF DRAWINGS

FIG. 1 is a schematic disassembled perspective view showing a configuration of a heater according to an embodiment,

FIG. 2 is a cross-sectional view taken along the II-II line in FIG. 1.

FIG. 3 is a cross-sectional view showing a terminal part and its periphery in a heater according to a first embodiment.

FIG. 4 is a cross-sectional view showing a terminal part and its periphery in a heater according to a second embodiment.

FIG. 5 is a cross-sectional view showing a terminal part and its periphery in a heater according to a third embodiment.

FIG. 6 is a cross-sectional view showing a terminal part and its periphery in a heater according to a fourth embodiment.

FIG. 7 is a cross-sectional view showing a terminal part and its periphery in a heater according to a fifth embodiment,

FIG. 8 is a cross-sectional view showing a terminal part and its periphery in a heater according to a sixth embodiment.

FIG. 9 is a cross-sectional view showing a terminal part and its periphery in a heater according to a seventh embodiment.

FIG. 10A and FIG. 10B are cross-sectional views showing terminal parts and their peripheries in heaters according to an eighth embodiment and a first modification of the eighth embodiment.

FIG. 11A and FIG. 11B are cross-sectional views showing terminal parts and their peripheries in heaters according to second and third modifications of the eighth embodiment.

FIG. 12 is a cross-sectional view showing a terminal part and its periphery in a heater according to a ninth embodiment,

FIG. 13 is a perspective view showing a terminal part in a heater according to a 10th embodiment.

FIG. 14 is a cross-sectional view showing a modification of a terminal conductor.

FIG. 15A and FIG. 15B are cross-sectional views showing one example of materials of a base body and an insulating portion.

### DESCRIPTION OF EMBODIMENTS

Below, ceramic structures in the present disclosure will foe explained by taking ceramic heaters as examples. The drawings which will be referred to below are schematic ones for convenience of explanation. Accordingly, sometimes details will be omitted. Further, Size ratios will not always coincide with the actual ones. Further, the heaters may be further provided with known components which are not shown in the drawings as well.

In the second and following embodiments, basically only differences from those in the previously explained embodiments will be explained. Matters which are not particularly referred to may be considered the same as those in the previously explained embodiments. Further, for convenience of explanation, for the configurations corresponding to each other among the plurality of embodiments, sometimes the same notations will be attached even if there are differences.

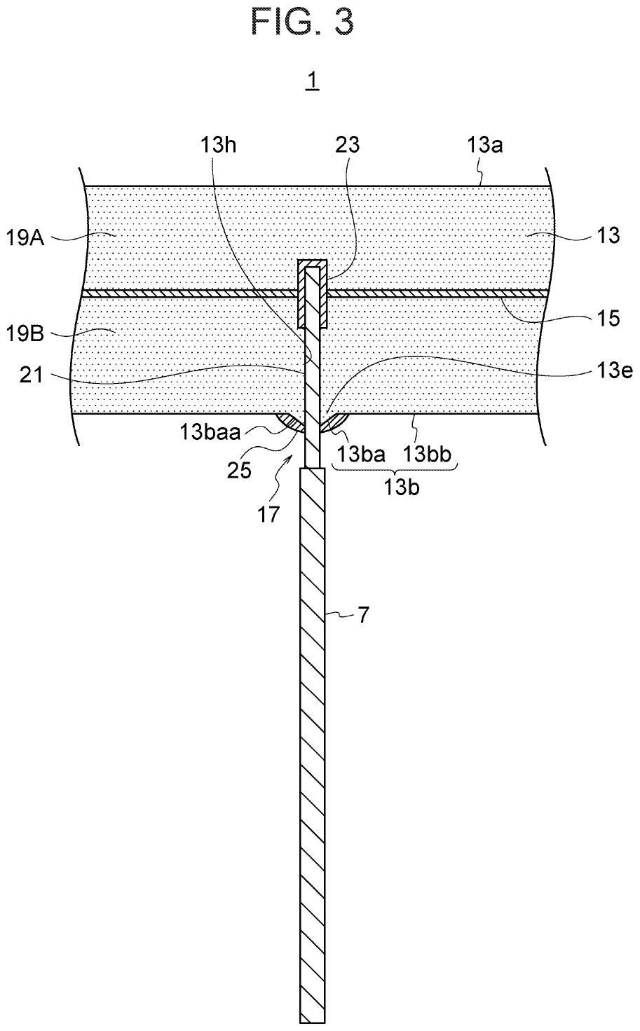

For the vertical cross-sectional views (FIG. 3 to FIG. 11B) of the configurations of single terminal parts and their surroundings, unless particularly explained, it may be concluded that the same vertical cross-sectional views are obtained when viewed from any direction around the above single terminal parts (around the center lines vertically extending on the drawing sheets).

### First Embodiment

### (Heater System)

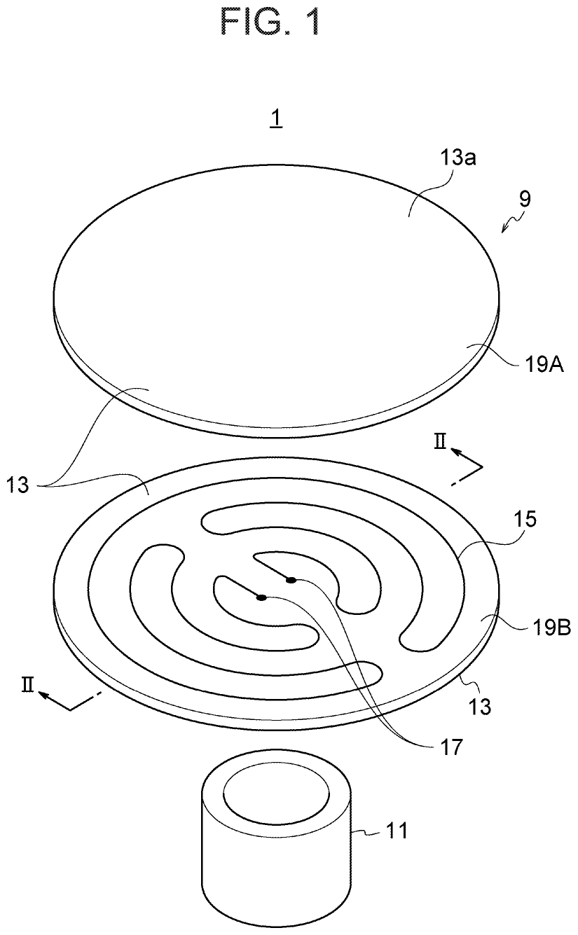

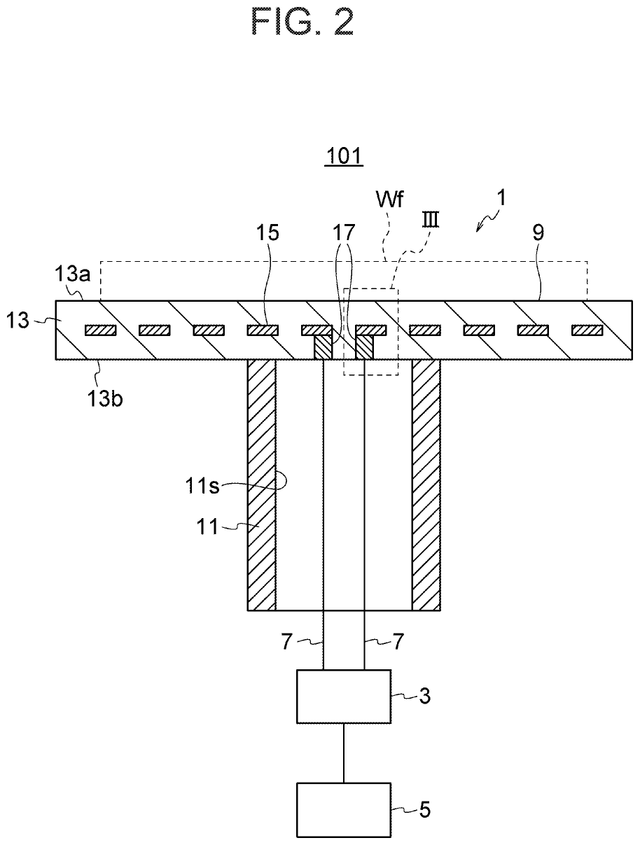

FIG. 1 is a schematic disassembled perspective view showing the configuration of a heater 1 according to an embodiment. FIG. 2 is a schematic view showing the configuration of a heater system 101 including the heater 1 in FIG. 1. In FIG. 2, for the heater 1, a cross-sectional view along the II-II line in FIG. 1 is shown. FIG. 1, for convenience, shows a disassembled heater 1 in order to show the structure of the heater 1. An actual heater 1 after completion need not be able to be disassembled as in the disassembled perspective view in FIG. 1.

Upward in the drawing sheets in FIG. 1 and FIG. 2 is for example vertically upward. However, the heater 1 need not utilize upward in the drawing sheets in FIG. 1 and FIG. 2 as vertically upward. In the following explanation, for convenience, sometimes the “tipper surface” and “lower surface” and other terms will be used where the upper directions of the drawing sheets in FIG. 1 and FIG. 2 are vertically upward. When simply referring to “when viewed on a plane”, unless particularly explained, it designates viewed from upward in the drawing sheets in FIG. 1 and FIG. 2.

The heater system 101 has a heater 1, a power supply part 3 (FIG. 2) which supplies power to the heater 1, and a control part (FIG. 2) which controls the power supply part 3. The heater 1 and the power supply part 3 are connected by wiring members 7 (FIG. 2). Note that, the wiring members 7 may be grasped as parts of the heater 1 as well. Further, the heater system 101, other than the configurations explained above, may have for example a fluid supply part which supplies gas and/or liquid to the heater 1.

(Heater)

The heater 1 for example has a substantially plate-shaped (disk-shaped in the example shown) heater plate 9 and a pipe 11 which extends from the heater plate 9 downward.

The heater plate 9 has a wafer Wf (FIG. 2) placed (superimposed) on an upper surface 13a thereof as one example of a heated object and directly contributes to heating of the wafer. The pipe 11 for example contributes to support of the heater plate 9 and protection of the wiring members 7. Note that, just the heater plate may be grasped as the heater as well.

(Heater Plate)

The upper surface 13a and lower surface 13b of the heater plate 9 are for example substantially planar. The planar shape and various dimensions of the heater plate 9 may be suitably set considering the shape and dimensions etc. of the heated object. For example, the planar shape is circular (example shown) or polygonal (for example rectangular). If showing one example of the dimensions, the diameter is 20 cm to 35 cm and the thickness is 4 mm to 30 mm.

The heater plate 9 is for example provided with an insulating base body 13, a resistance heating element 15 (one example of the internal conductor) buried in the base body 13, and terminal parts 17 for supplying power to the resistance heating element 15. By current running in the resistance heating element 15, heat is generated according to Joule's law. In turn, the wafer Wf placed on the upper surface 13a of the base body 13 is heated.

(Base Body)

The outer shape of the base body 13 configures the outer shape of the heater plate 9. Accordingly, an explanation according to the shape and dimensions of the heater plate 9 explained above may be grasped as an explanation of the outer shape and dimensions of the base body 13 as it is. The material of the base body 13 is for example ceramic. The ceramic is for example a sintered body containing aluminum nitride (AlN), aluminum oxide (Al₂O₃, alumina), silicon carbide (SiC), silicon nitride (Si₃N₄), or the like as the principal constituent. Note that, the principal constituent is for example a constituent accounting for 50 mass % or more or 80 mass % or more of the material (same is true for the following explanation).

In FIG. 1, the base body 13 is configured by a first insulation layer 19A and second insulation layer 19B. Note that, the base body 13 may be prepared by materials (for example ceramic green sheets) forming the first insulation layer 19A and second insulation layer 19B stacked on each other or may be prepared by a method different from such a method and may be only conceptually grasped as being configured by the first insulation layer 19A and second insulation layer 19B due to presence of the resistance heating element 15 etc. after completion.

The thicknesses of these insulation layers may be suitably set. Also, the ratio occupied of each insulation layer in the thickness of the base body 13 may be suitably set. As will be explained later, the technique according to the present embodiment can be applied to a heater in which the thickness from the lower surface 13b (in more detail, a main region 13bb which will be explained later) of the base body 13 up to the internal conductor (resistance heating element 15) in the lowermost layer (thickness of the second insulation layer 19B) is relatively thin. When explaining one example of the thickness of the second insulation layer 19B which is relatively thin in this way, it is for example 1 mm to 3 mm. In this case, for example, the thickness of the base body 13 may be made 4 mm to 6 mm.

(Resistance Heating Element)

The resistance heating element 15 extends along (for example parallel to) the upper surface 13a and the lower surface 13b of the base body 13. Further, the resistance heating element 15, when viewed on a plane, for example, extends covering over substantially the entire surface of the base body 13. In FIG. 1, the resistance heating element 15 is positioned between the first insulation layer 19A and the second insulation layer 19B.

The specific pattern (route) of the resistance heating element 15 when viewed on a plane may be made a suitable one. For example, only one resistance heating element 15 is provided in the heater plate 9 and extends from one end to the other end without crossing itself. Further, in the example shown, the resistance heating element 15, in each of the regions obtained by dividing the heater plate 9 into two, extends so as to weave back and forth (meander) in a circumferential direction. Other than this, for example, the resistance heating element 15 may spirally extend or may extend so as to linearly weave back and forth in one radial direction.

The shape when locally viewing the resistance heating element 15 may be made a suitable one. For example, the resistance heating element 15 may be a layered conductor which is parallel to the upper surface 13a and lower surface 13b, may be coil shaped (spring shaped) wound using the above route as the axis, or may be formed in a mesh shape. Also, the dimensions in the various shapes may be suitably set.

The material of the resistance heating element 15 is a conductor (for example metal) which generates heat by flow of current. The conductor may be suitably selected. For example, it is tungsten (W), molybdenum (Mo), platinum (Pt), indium (In), or an alloy containing them as principal constituents. Further, the material of the resistance heating element 15 may be one obtained by firing a conductive paste including the metal as described before as well. That is, the material of the resistance heating element may be one containing glass powder and/or ceramic powder or other additives (from another viewpoint, an inorganic insulation substance).

(Terminal Parts (Outline))

The terminal parts 17, for example, are connected to the two ends of the resistance heating element 15 in the long direction and, at the positions of the two ends, penetrate through parts of the base body 13 on the lower surface 13b side (second insulation layer 19B) to be exposed from the lower surface 13b. Due to this, it becomes possible to supply power from the exterior of the heater plate 9 to the resistance heating element 15. The pair of terminal parts 17 (two ends of the resistance heating element 15) are for example positioned on the center side in the heater plate 9. Note that, three or more terminal parts 17 supplying power to one resistance heating element 15 may be provided or two or more sets of terminal parts 17 supplying power to two or more (for example two or more layers of) resistance heating elements 15 may be provided as well.

(Pipe)

The pipe 11 is hollow shape opened at the top and bottom (two sides in the axial direction). From another viewpoint, the pipe 11 has a space 11s running through it from the fop to bottom. The shapes of a transverse cross-section (cross-section perpendicular to the axial direction) and vertical cross-section (cross-section parallel to the axial direction, the cross-section shown in FIG. 2) in the pipe 11 may be suitably set. In the example shown, the pipe 11 is cylinder shaped with a constant diameter relative to the position in the axial direction. Naturally, the pipe 11 may differ in diameter according to the position in the height direction as well. Further, specific values of dimensions of the pipe 11 may be suitably set. Although not particularly shown, in the pipe 11, a flow path in which gas or liquid flows may be formed as well.

The pipe 11 may be configured by ceramic or another insulation material or may be configured by a metal (conductive material). As specific materials of the ceramic, for example, ones (AlN etc.) given in the explanation of the base body 13 may be utilized. Further, the material of the pipe 11 may be the same as the material of the base body 13 or may be different from the latter.

The base body 13 and the pipe 11 may be fixed together out by a suitable method. For example, the two may be fixed together by an adhesive (not shown) interposed between the two, may be fixed together by solid phase bonding without an adhesive interposed between the two, or may be mechanically fixed together by utilizing bolts and nuts (both not shown).

The adhesive may be an organic material, may be an inorganic material, may be a conductive material, or may be an insulation material. Specifically, as the adhesive, for example, use may be made of a glass-based one (glass bonding may be utilized). As the solid phase bonding, for example, diffusion bonding may be utilized. In the diffusion bonding, the base body 13 and the pipe 11 are bonded by hot pressing. The diffusion bonding includes not only one making the base body 13 and the pipe 11 directly abut against each other, but also one arranging a material for promoting bonding between the two. The material may be in a solid phase state or liquid phase state at the time of bonding.

(Wiring Members)

The wiring members 7 are inserted in the space 11s in the pipe 11. In a plane perspective, the plurality of terminal parts 17 are exposed from the base body 13 in a region in the heater plate 9 which is exposed to the space 11s. Further, the wiring members 7 are connected at single ends to the plurality of terminal parts 17.

The plurality of wiring members 7 may be flexible electrical wires, may be rod-shaped conductors without flexibility, or may be a combination of the same. Further, the plurality of flexible electrical wires may be bundled together so as to become like one cable or need not be bundled together. Further, the connections between the wiring members 7 and the terminal parts 17 may be suitable ones. For example, the two may be joined by a conductive bonding material. Further, for example, the two may be screwed together by forming a male screw in one and forming a female screw in the other,

(Details of Terminal Parts)

FIG. 3 is an enlarged view of a region III in FIG. 2.

Each terminal part 17 has a shaft-shaped (pin-shaped) terminal conductor 21 made of metal. The terminal conductor 21 is buried in the base body 13 so as to vertically pass through the portion (second insulation layer 19B) in the base body 13 which is lower than the resistance heating element 15. The upper end side portion of the terminal conductor 21 is connected to the resistance heating element 15. Further, the lower end side portion of the terminal conductor 21 is connected to the wiring member 7.

The specific shape and various dimensions of the terminal conductor 21 may be suitably set. For example, in at least a range where the terminal conductor 21 is buried in the base body 13 (for example in the entirety of the terminal conductor 21), the terminal conductor 21 linearly extends, and the shape and size of the terminal conductor 21 transverse cross-section are constant in the long direction. The terminal conductor 21 may be solid as illustrated or may be hollow unlike the example shown. The shape of the transverse cross-section may be made circular or polygonal or another suitable shape. The terminal conductor 21 may have a specific shape (for example a male screw) for connection with the wiring member 7 as well in the portion exposed to the exterior of the base body 13. When explaining one example of the diameter (maximum diameter) of the terminal conductor 21, it is 0.05 mm to 10 mm.

The material of the terminal conductor 21 may also foe suitably set. For example, as the material of the terminal conductor 21, there can be mentioned W, Mo, or Pt. The material of the terminal conductor 21 may be the same as or different from the material of the internal conductor (resistance heating element 15) and/or the material of the wiring member 7.

The terminal conductor 21 and the internal conductor (resistance heating element 15) are for example connected at the side surface of the terminal conductor 21 by projection of the terminal conductor 21 higher than the resistance heating element 15. However, the two, unlike the example shown, may be connected at the upper end surface of the terminal conductor 21 by the upper end surface being positioned at the height of the resistance heating element 15.

Further, the connection (for example bonding) between the terminal conductor 21 and the resistance heating element 15 may be carried out by direct abutment of the two or may be carried out by interposition of a material different from the two and/or another member between the two. In the example shown, a conductive bonding material 23 is interposed between the resistance heating element and the terminal conductor 21. The material of the bonding material 23 may be made a suitable one. For example, the bonding material 23 is configured by a composite material containing the same constituents as the material of the resistance heating element and the same constituents as the material of the base body 13. As such a composite material, for example, there can be mentioned one containing W and AlN.

The connection of the terminal conductor 21 and the wiring member 7 may be carried out by a suitable method as given in the explanation of the wiring member 7. In the example shown, a not shown hole (recessed portion or through hole) is formed in the upper surface of the wiring member 7, and the lower portion of the terminal conductor 21 is inserted in the hole. In this case, for example, a male screw is formed in the lower portion of the terminal conductor 21, a female screw is formed in the hole of the wiring member 7, and the two are screwed together. However, the two may also be joined not by screwing, but by a conductive bonding material which is interposed between the inner surface of the hole of the wiring member 7 and the outer surface of the terminal conductor 21. Further, in the explanation of the embodiments, the terminal conductor 21 and the wiring member 7 will be explained as different members. However, it is also possible to integrally form the two by the same material.

(Details of Surroundings of Terminal Parts)

The lower surface 13b of the base body 13 has adjacent regions 13ba which surround the terminal parts 17 and a main region 13bb which surrounds the adjacent regions 13ba. The adjacent regions 13ba have inclined surfaces 13baa. Due to this, projecting portions 13e are configured at the surroundings of the terminal parts 17.

The adjacent regions 13ba are regions contiguous with the terminal parts 17 and contact the terminal conductors 21 in the present embodiment. The adjacent regions 13ba may be defined as the regions over the entire circumferences of the terminal parts 17 when viewed on a plane. The lengths (below, referred to as the widths of the adjacent regions 13ba) from the inner edges of the adjacent regions 13ba (outer surfaces of the terminal parts 17) up to the outer edges of the adjacent regions 13ba (inner edges of the main region 13bb) may be suitably set. For example, the widths of the adjacent regions 13ba may be made 1/10 or more, ⅕ or more, ½ or more, or 1 time or more relative to the diameters of the terminal parts 17 (maximum diameters where not circular) at the height of the surroundings of the adjacent regions 13ba (main region 13bb in the present embodiment). Further, the above widths may be times or less, 5 times or less, or 1 time or less relative to the above diameters. The above lower limits and upper limits may be suitably combined unless they are contradictory. Further, for example, the widths of the adjacent regions 13ba may be made 1/10 or less, 1/50 or less, or 1/100 or less relative to the diameter of the base body 13 (minimum diameter where not circular). Further, for example, the widths of the adjacent regions 13ba may be made 10 mm or less, 5 mm or less, or 1 mm or less.

The main region 13bb, in the present embodiment, is for example the entire region of the lower surface 13b excluding the adjacent, regions 13ba and accounts for the majority of the lower surface 13b. The main region 13bb is for example a region accounting for 80% or more, 90% or more, or 95% or more of the area of the lower surface 13b. The main region 13bb is shaped as a flat surface.

The inclined surfaces 13baa included in the adjacent regions 13ba are inclined so as to be positioned lower the closer to the terminal parts 17 and reach (contact) the terminal parts 17 (here, the terminal conductors 21). The “lower” referred to here is, in other words, the side away from the internal conductor (resistance heating element 15) or the opposite side to the side where the upper surface 13a on which the wafer Wf is superimposed faces. Here, the “inclined” referred to here means positioning on a lower side or upper side the closer to the terminal parts 17 when viewed on a plane.

The inclined surfaces 13baa may be provided over the entire circumferences of the terminal parts 17 or may be provided in only part around the terminal parts 17 (may be interrupted around the terminal parts 17). Further, the inclined surfaces 13baa may be given the same shapes and dimensions over the entire circumferences of the terminal parts 17 or may be different in inclination angles, the positions in the vertical direction of the inner edges (edge parts contacting the terminal parts 17), and/or distances of the outer edges (for example the portions where the positions in the vertical direction become the same as the main region 13bb) from the terminal parts 17 according to the positions around the terminal parts 17. From another viewpoint, the projecting portions 13e may have frustum shapes in which the bases are circles, or shapes other than that.

Note that, in the explanations of the present embodiment and the embodiments which will be explained later, for convenience, mainly a case where shapes of the inclined surfaces and their peripheries have constant shapes and dimensions over the entire circumferences of the terminal parts will be taken as an example. In this case, the inclined surfaces 13baa are over the entire circumferences of the terminal parts, therefore the adjacent regions 13ba and the inclined surfaces 13baa may be grasped as being same.

The shapes and dimensions of the inclined surfaces 13baa or projecting portions 13e may be suitably set. For example, in the vertical cross-sections as shown in FIG. 3, the inclined surfaces 13baa may be straight, may be curved so as to be concave facing downward (that is, shapes where the inclination angles relative to the main region 13bb become larger the closer to the terminal parts 17), may be curved so as to be convex facing downward (that is, a shape where the inclination angles relative to the main region 13bb become smaller the closer to the terminal parts 17) or may be a combination of the same. The heights of the projecting portions 13e may be made for example 1/100 or more, 1/50 or more, 1/10 or more, or 1 time or more relative to the diameters of the terminal parts 17 (maximum diameters when not circular) at the heights of the surroundings of the adjacent regions 13ba (main region 13bb in the present embodiment). Further, the heights of the projecting portions 13e may be made 2 times or less, 1 time or less, ⅕ or less, or 1/10 or less relative to the above diameters. The above lower limits and upper limits may be suitably combined unless they are contradictory. Further, for example, the heights of the projecting portions 13e are 0.05 mm or more or 0.1 mm or more. Further, they are 2 mm or less, 1 mm or less, or 0.6 mm or less. The lower limits and the upper limits may be suitably combined.

The boundaries between the terminal parts 17 and the adjacent regions 13ba (inclined surfaces 13baa) may be sealed by a sealing material 25 adhered to the two as well. The material of the sealing material 25 may be made a suitable one. For example, it may be a general glass seal, or use may be made of a CaO—Al₂O₃—Y₂O₃ adhesive.

(Method for Manufacturing Heater)

In a method for manufacturing the heater 1, for example, the heater plate 9, pipe 11, wiring members 7, and the like are separately prepared from each other. After that, these members are fixed to each other. However, part or all of the heater plate 9 and the pipe 11 may be prepared together as well. The methods for manufacturing the pipe 11 and the wiring members 7 may be made for example the same as known various methods.

The method for manufacturing the heater plate 9 may be made for example the same as various known methods excluding the method of preparation of the terminal parts 17 and inclined surface 13baa (projecting portions 13e). For example, the heater plate 9 may be prepared by firing a laminate of ceramic green sheets for forming the first insulation layer 19A and second insulation layer 19B in which a conductive paste forming the resistance heating element 15 is arranged. Further, the heater plate 9 may be prepared by arranging a coil forming the resistance heating element 15 and raw material powder of ceramic forming the base body 13 in a die and hot pressing it (that is, using a hot press method).

The method of providing the terminal parts 17 in the heater plate 9 is for example as follows.

In a case where ceramic green sheets are fired to prepare the heater plate 9, for example, holes 13h are formed in the ceramic green sheets configuring parts in the base body 13 into which the terminal parts 17 are inserted. The terminal parts 17 (terminal conductors 21 in the present embodiment, in other words, shaft-shaped metal members) are inserted into these holes 13h. Note that, on at least part of the inner surfaces of the holes 13h and the outer surfaces of the upper end side portions of the terminal parts 17, conductive pastes which become the bonding materials may be coated. After that, the ceramic green sheets are fired.

In the case where the terminal parts 17 are provided in this way, the base body 13 may fasten the terminal parts 17 by contraction of the ceramic at the time of firing as well. For this purpose, the diameters of the holes 13h before firing may be made sizes which are equal to or larger than the diameters of the terminal parts 17 and which become smaller than the diameters of the terminal parts 17 by contraction after firing (when assuming that there are no terminal parts 17). The difference between the diameters of the terminal parts 17 and the diameters of the holes 13h after contraction when assuming no terminal parts 17 may be made for example 0.2 mm to 0.4 mm.

Further, where the heater plate 9 is prepared according to the hot pressing method, for example, the upper end side portions of the terminal parts 17 (terminal conductors 21 in the present embodiment, in other words, shaft-shaped metal members) may be placed in a die for hot pressing the raw material powder of ceramic.

The inclined surfaces 13baa may be formed by a suitable method. For example, the surfaces forming the inclined surfaces 13baa may be formed by pushing a die against the surface of a ceramic green sheet which forms the lower surface 13b of the base body 13 as well. Further, in the hot press method, for example, the die for hot pressing the raw material powder of ceramic may have a surface forming the inclined surfaces 13baa as well. Further, for example, when the base body 13 is reduced in, diameter by firing, the portions in the base body 13 which are closely adhered to the terminal parts 17 may remain since they cannot contract, and thereby form the inclined surfaces 13baa as well. Further, for example, shaping by the die described above and formation by contraction may be combined as well.

As explained above, in the present embodiment, the heater 1 as the ceramic structure constituted has the base body 13, internal conductor (resistance heating element 15), and terminal parts 17. The base body 13 is made of ceramic and is a plate shape having an upper surface 13a on which the wafer Wf is superimposed and a lower surface 13b on the opposite side to the upper surface 13a. The resistance heating element 15 is positioned inside the base body 13. The terminal parts 17 are electrically connected to the resistance heating element 15, have at least parts positioned inside the base body 13 and are exposed from the lower surface 13b of the base body 13 to the exterior of the base body 13. The lower surface 13b of the base body 13 has the adjacent regions 13ba which surround the terminal parts 17. The adjacent regions 13ba have the inclined surfaces 13baa in portions reaching the terminal parts 17.

Accordingly, compared with an aspect where the adjacent regions 13ba reach the terminal parts 17 while flush (without inclination) relative to the main region 13bb, various advantageous effects can be obtained. Specifically, they are as follows.

For example, in the present embodiment, the inclined surfaces 13baa are positioned lower the closer to the terminal part 17 side and configure the projecting portions 13e. In this case, for example, the heat which is transferred from the resistance heating element 15 through the terminal parts 17 to the projecting portions 13e cannot be transferred from the projecting portions 13e in the horizontal direction in the base body 13, but is transferred upward in the base body 13 since there is no ceramic configuring the base body 13 at the surroundings of the projecting portions 13e. Due to this, the upper surface 13a can be efficiently heated.

Further, in the present embodiment, the terminal parts 17 have the terminal conductors 21. The terminal conductors 21 are at least partially positioned inside the base body 13 and are exposed from the lower surface 13b of the base body 13 to the exterior of the base body 13. The adjacent regions 13ba are adjacent to the terminal conductors 21 and surround the terminal conductors 21. In this case, for example, compared with the other embodiments which will be explained later, the configuration is simple. As a result, for example, the material cost can be reduced, and the manufacturing process can be simplified.

### Second Embodiment

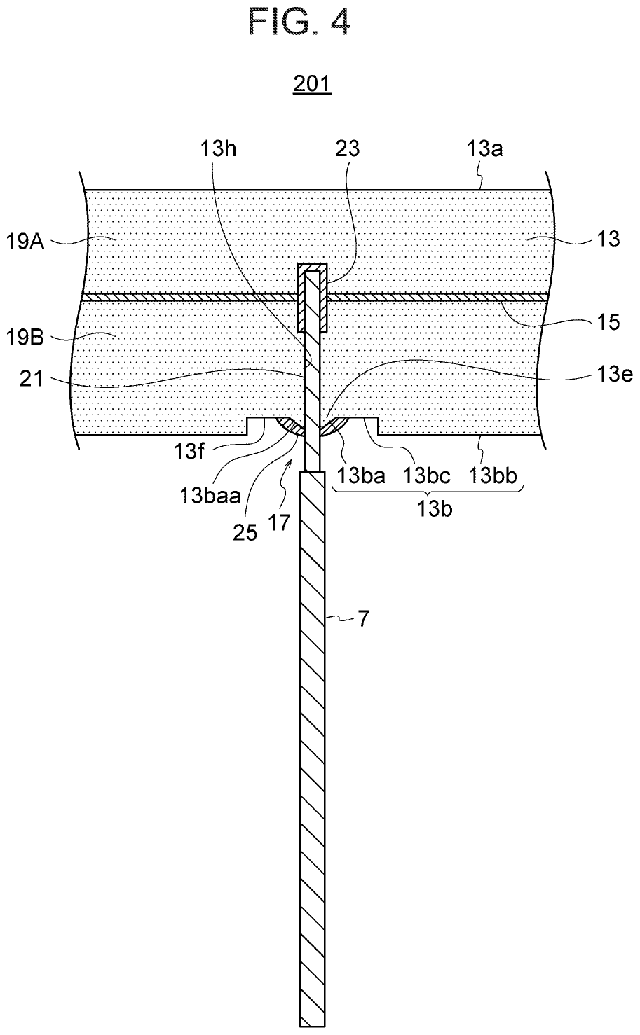

FIG. 4 is a view showing the configuration of a principal part in a heater 201 according to a second embodiment and corresponds to FIG. 3 for the first embodiment.

The heater 201 is configured as the heater 1 in the first embodiment provided with recessed portions 13f at the lower surface 13b. Specifically, this is as follows.

The lower surface 13b of the heater 201 has adjacent regions 13ba the same as the first embodiment, intermediate regions 13bc surrounding the adjacent regions 13ba, and an outer side region (main region 13bb) surrounding the intermediate regions 13bc. The intermediate regions 13bc are positioned higher than the main region 13bb and configure the recessed portions 13f. The projecting portions 13e project inside the recessed portions 13f. Note that, the shapes and sizes of the projecting portions 13e themselves may be made the same as those of the projecting portions 13e in the first embodiment. The main region 13bb may be made the same as the main region 13bb in the first embodiment except for the point that the area is reduced from that in the first embodiment by the sizes of the intermediate regions 13bc.

The intermediate regions 13bc may be defined as regions over the entire circumferences of the adjacent regions 13ba when viewed on a plane. The shapes and dimensions of the intermediate regions 13bc and recessed portions 13f may be suitably set.

For example, in the example shown, the intermediate regions 13bc are plane-shaped parallel to the main region 13bb in their entirety. In turn, the recessed portions 13f are shaped with plane-shaped bottom surfaces parallel to the main region 13bb and side surfaces perpendicular to the main region 13bb. However, the recessed portions 13f may be shaped tapered or reverse tapered at the side surfaces and need not have plane-shaped bottom surfaces.

Further, for example, the shapes of the outer edges of the intermediate regions 13bc (recessed portions 13f) when viewed on a plane may be circular or may be rectangular or other polygonal shapes. Further, when viewed on a plane, the shapes of the outer edges of the intermediate regions 13bc may be similar shapes or need not be similar shapes relative to the shapes of the outer edges of the projecting portions 13e (inner edges of the intermediate regions 13bc).

When viewed on a plane, the lengths from the outer edges of the projecting portions 13e up to the outer edges of the intermediate regions 13bc (inner edges of the main region 13bb) (below, referred to as the widths of the intermediate regions 13bc) may be suitably set. For example, the widths of the intermediate regions 13bc may be smaller than, equal to, or larger than the widths of the adjacent region 13ba.

The depths of the recessed portions 13f from the main region 13bb, for example, at the outer edges of the projecting portions 13e (from another viewpoint, the deepest portions in the recessed portions 13f), are larger than the heights (amounts of projection) of the projecting portions 13e from the intermediate regions 13bc (deepest portions in the recessed portion 13f). Accordingly, the apex parts of the projecting portions 13e are positioned higher than the main region 13bb (do not project lower than the main region 13bb). However, the apex parts of the projecting portions 13e may be positioned at heights equal to the main region 13bb or may be positioned lower than the main region 13bb. The difference between the depths of the recessed portions 13f from the main region 13bb and the heights of the projecting portions 13e from the intermediate regions 13bc may be suitably set. For examples, the above difference may be made 1/10 or more or ½ or more or 1 time or more relative to the heights of the projecting portions 13e. Further, the above difference may be made 10 times or less, 2 times, ½ or less, or ⅕ or less relative to the heights of the projecting portions 13e. The above lower limits and upper limits may be suitably combined unless they are contradictory.

The recessed portions 13f may be formed by a suitable method. For example, the recessed portion 13f may be formed by pushing a die against the ceramic green sheets, cutting the ceramic green sheets, or laser machining the ceramic green sheets. Further, for example, when the base body 13 is prepared by the hot press method, the recessed portions 13f may be formed by the die hot pressing the ceramic raw material powder having shapes corresponding to the recessed portions 13f.

In the present embodiment as well, due to the inclined surfaces 13baa (projecting portions 13e), the same effects as those by the first embodiment are exhibited. Specifically, for example, it becomes easier to transfer heat which was transferred from the resistance heating element 15 through the terminal parts 17 to the projecting portions 13e upward.

Further, in the present embodiment, the lower surface 13b of the base body 13 has the recessed portions 13f. The projecting portions 13e project inside the recessed portions 13f. In this case, for example, the effects by the projecting portions 13e described above are obtained, while the thickness of the base body 13 can be secured in the main region 13bb. As a result, for example, the heat capacity of the base body 13 can be made larger or the strength of the base body 13 can be improved. Further, the lower surface 13b (main region 13bb) is sometimes polished. In this case, a probability of the projecting portions 13e obstructing polish can be lowered.

Note that, for example, depending on the configuration of the base body 13, sometimes a case where a large heat capacity is not secured lower than the resistance heating element 15 is better. Further, for example, sometimes when no recessed portions 13f are formed, the process of formation of the projecting portions 13e can be made easier. Further, for example, if the recessed portions 13f are formed, compared with an aspect where the thickness in the main region 13bb is the same as that in the present embodiment and the recessed portions 13f are not provided, the bonding areas between the terminal conductors 21 and the base body 13 are reduced. Accordingly, presence of formation of the recessed portions 13f (which of the first embodiment and the second embodiment is to be selected) may be judged in accordance with the specifications required.

### Third Embodiment

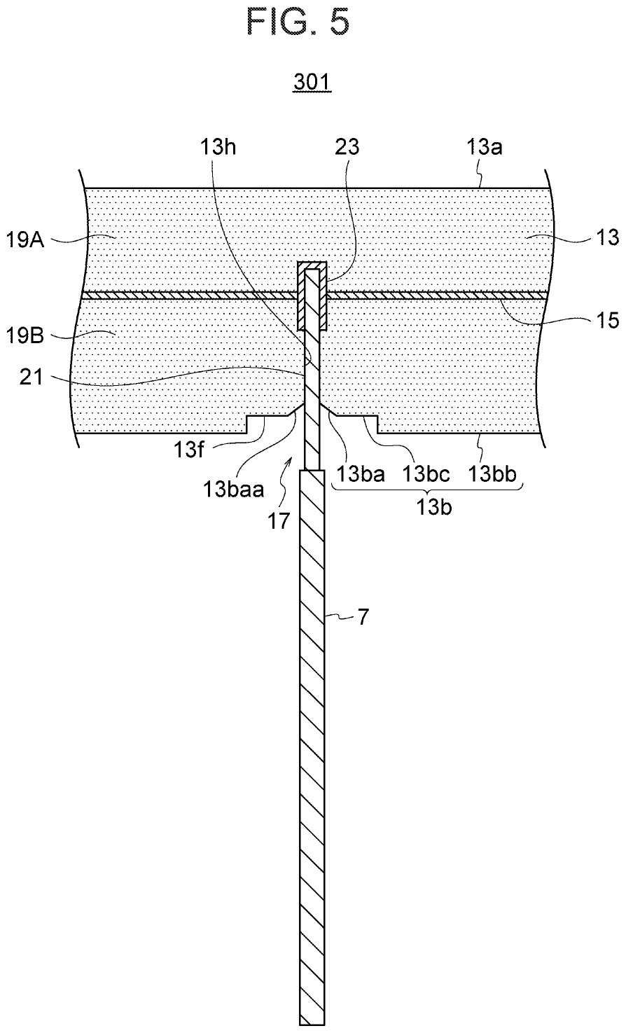

FIG. 5 is a view showing the configuration of a principal part in a heater 301 according to a third embodiment and corresponds to FIG. 3 for the first embodiment.

In the second embodiment, the inclined surfaces 13baa were inclined so as to be positioned lower (side away from the internal conductors) the closer to the terminal parts 17 from the intermediate regions 13bc when viewed on a plane and thereby configure the projecting portions 13a. Contrary to this, in the present embodiment, the inclined surfaces 13baa are inclined so as to be positioned higher (side approaching the internal conductors) the closer to the terminal parts 17 from the intermediate regions 13bc when viewed on a plane. Further, the inclined surfaces 13baa configure chamfered surfaces obtained by chamfering the corner portions formed by the intermediate regions 13bc and the inner surfaces of the holes 13h (from another viewpoint, notches or recessed portions in the intermediate regions 13bc). The explanation for the shapes and dimensions of the inclined surfaces 13baa (projecting portions 13e) in the first embodiment may be employed for the explanation concerning the shapes and dimensions of the inclined surfaces 13baa in the present embodiment by suitably reversing the top and the bottom (or the recesses and the protrusions).

In FIG. 5, in the same way as the second embodiment, the recessed portions 13f (intermediate regions 13bc) are provided. However, in the same way as the first embodiment, the recessed portions 13f need not be provided. The inclined surfaces 13baa (adjacent regions 13ba) and the main region 13bb may be contiguous. That is, the inclined surfaces 13baa may configure chamfered surfaces obtained by chamfering the corner portions formed by the inner surfaces of the holes 13h and the main region 13bb as well. Further, in FIG. 5, unlike the first and second embodiments, the sealing material 25 for sealing the boundaries between the inclined surfaces 13baa and the side surfaces of the terminal parts 17 is not provided. However, the sealing material 25 may be provided as well.

The method of formation of the inclined surfaces 13baa in the present embodiment may be made the same as the methods of formation of the inclined surfaces in the first and second embodiments. For example, the inclined surfaces 13baa may be formed by pushing a die against ceramic green sheets or by making the die for hot pressing a shape corresponding to the inclined surfaces 13baa. Further, for example, unlike the inclined surfaces 13baa configuring the projecting portions 13e, it is also possible to form the inclined surfaces 13baa by cutting or laser machining in the same way as the recessed portions 13f.

As explained above, in the present embodiment as well, the lower surface 13b of the base body 13 has the inclined surfaces 13baa reaching the terminal parts 17. As a result, various effects are exhibited compared with a case where no inclined surfaces 13baa are provided.

For example, in the present embodiment, the lower surface 13b of the base body 13 further has surrounding regions (intermediate regions 13bc in the example in FIG. 5) which surround the adjacent regions 13ba (inclined surfaces 13baa). The base body 13 has holes 13h which are opened at the lower surface 13b and in which the terminal parts 17 are inserted. The inclined surfaces 13baa are positioned higher (side approaching the internal conductors) the closer to the terminal parts 17, and configure chamfered surfaces which are obtained by chamfering the corner portions formed by the surrounding regions and the inner surface of the hole 13h.

In this case, for example, stress caused by the loads which are applied from the terminal parts 17 to the inner surfaces of the holes 13h in the horizontal direction are dispersed to the inclined surface 13baa sides, therefore, the stress becomes harder to concentrate at the lower edge parts of the holes 13h. As a result, for example, the probability of occurrence of cracks in the lower surfaces 13b can fee lowered. Note that, in accordance with the specifications etc. required by the base body 13, the inclination direction of the inclined surfaces 13baa (to which of upward and downward, they are to be inclined) may be suitably selected.

Further, in the present embodiment, the base body 13 further has an outer side region (main region 13bb in the example in FIG. 5) which surrounds the surrounding regions (intermediate regions 13bc in the example in FIG. 5). The intermediate regions 13bc are positioned higher than the main region 13bb and configure the recessed portions 13f.

In this case, for example, from another viewpoint, the main region 13bb is made thicker. Therefore, in the same way as the second embodiment, it is made easy to secure the heat capacity of the base body 13 in the main region 13bb or secure the strength of the base body 13. Note that, as given also in the explanation of the second embodiment, any formation of the recessed portions 13f may be selected in accordance with the specifications etc. required.

### Fourth Embodiment

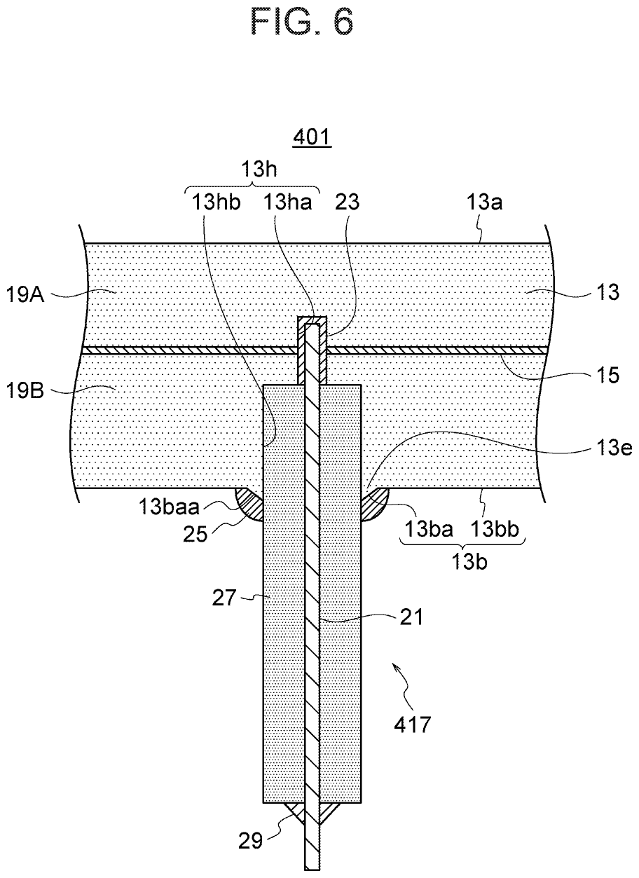

FIG. 6 is a view showing the configuration of a principal part in a heater 401 according to a fourth embodiment and corresponds to FIG. 3 for the first embodiment (however, illustration of the wiring members 7 is omitted).

In the heater 401, the configuration of the terminal parts 417 differs from the configuration of the terminal parts 17 in the first embodiment. Specifically, the terminal parts 417 have the terminal conductors 21 and insulating portions 27 in which the terminal conductors 21 are buried.

The terminal conductors 21 are the same as those in the first embodiment and have upper end side portions and the lower end side portions extending outward from the insulating portions 27. The upper end side portions of the terminal conductors 21 are connected to the resistance heating element 15 in the same way as the first embodiment. The lower end side portions of the terminal conductors 21 are connected to the wiring members 7 in the same way as the first embodiment although illustration is omitted here.

In the insulating portions 27, the upper end side portions are buried in portions lower than the resistance heating element in the base body 13, while the lower end side portions extend outward (are exposed) from the lower surface 13b of the base body 13. Further, the adjacent regions 13ba surrounding the terminal parts 417, unlike the first embodiment, are contiguous with the insulating portions 27 instead of the terminal conductors 21. The configurations of the adjacent regions 13ba (projecting portions 13e) and main region 13bb are basically the same as those in the first embodiment.

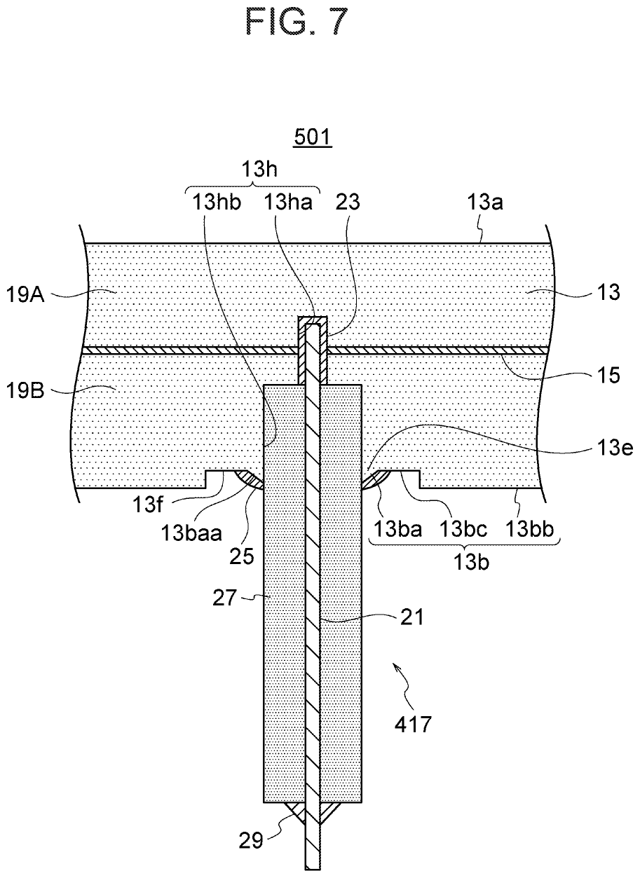

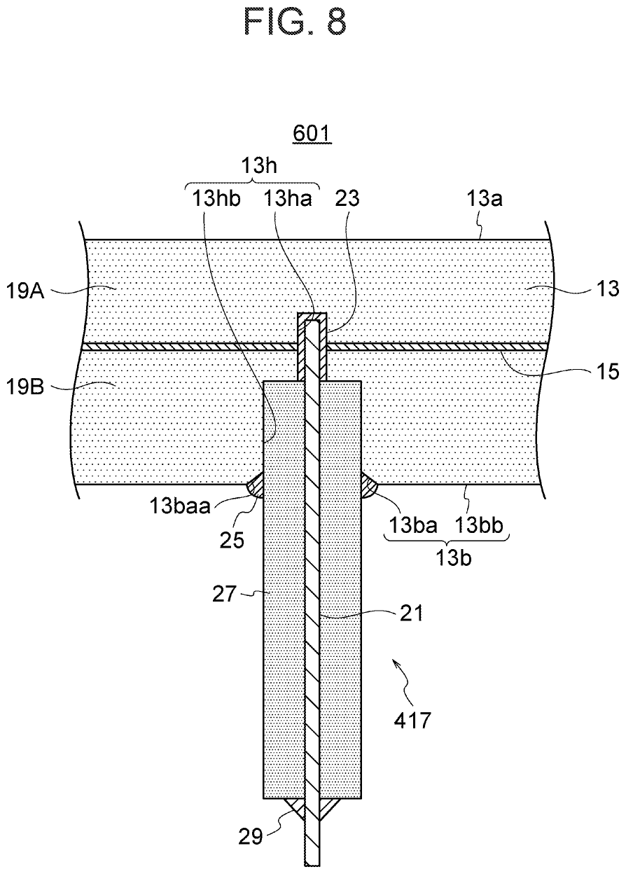

Note that, in the example shown, the positions where the insulating portions 27 and the adjacent regions 13ba are contiguous are in the middle of the side surfaces of the insulating portions 27, and the insulating portions 27 extend outward from the adjacent regions 13ba. However, the positions where the two are contiguous may be made the lower ends of the side surfaces of the insulating portions 27 as well. The same is true for the other embodiments (FIG. 7 and FIG. 8 etc.) having insulating portions 27 and differing in modes of the adjacent regions 13ba.

The insulating portions 27 are for example made of ceramic. The ceramic may be the same one as the ceramic configuring the base body 13 or may be different from the latter. In the latter case, the insulating portions 27 and the base body 13 may have the same principal constituents or may have different principal constituents.

Note that, FIG. 6 clearly shows the boundaries between the base body 13 and the insulating portions 27 by giving the two different hatchings. However, in a case where the materials of the base body 13 and the insulating portions 27 are the same or the like, the boundaries of the two need not be clear. The same is true for the base bodies and insulating portions shown in the other drawings which will be explained later.

The specific shapes and various dimensions of the insulating portions 27 may be suitably set. For example, in at least a range where the insulating portions 27 are buried in the base body 13 (for example in the entirety of the insulating portions 27), the insulating portions 27 extend straight, and the shapes and sizes of the outer edges of the transverse cross-sections of the insulating portions 27 are constant in the long direction. The shapes of the transverse cross-sections may be made circular, polygonal, or other suitable shapes. When explaining one example of the diameters of the insulating portions 27 (the maximum diameters when not circular), for example, they may be made 1.5 times or more or 3 times or more relative to the diameters of the terminal conductors 21 (the maximum diameter when not circular). Further, the diameters of the insulating portions 27 (the maximum diameters when not circular) may be made 20 times or less, 10 times or less, 5 times or less, or 2 times or less relative to the diameters of the terminal conductors 21 (the maximum diameter when not circular). The lower limits and the upper limits may be suitably combined unless they are contradictory. Further, for example, the diameters of the insulating portions 27 (the maximum diameters when not circular) may be made 0.1 mm or more, 1 mm or more, 5 mm or more, or 10 mm or more. Further, they may be made 100 mm or less, 50 mm or less, 20 mm or less, or 10 mm or less. The lower limits and the upper limits may be suitably combined unless they are contradictory.

Note that, as described above, as the diameters of the terminal parts 417, values larger than the diameters of the terminal parts 17 (terminal conductors 21) illustrated in the first embodiment were exemplified. However, the dimensions of the adjacent regions 13ba and inclined surfaces 13baa (projecting portions 13e) etc. (sizes relative to the terminal parts or other members or absolute values) illustrated in the first embodiment may applied to the present embodiment by replacing the terminal parts 17 with the terminal parts 417 as well.

On the lower surfaces of the insulating portions 27, gaps between the through holes in the insulating portions 27 and the terminal conductors 21 may be sealed by the sealing material 29 as well. The material of the sealing material 29 may be the same as or may be different from the material of the sealing material 25. As the specific material of the sealing material 29, ones given in the explanation of the sealing material 25 can be utilized.

The method for manufacturing the terminal parts 417 is as follows. First, insulating portions 27 made of raw ceramic material before firing are prepared. The insulating portions 27 are formed in tubular shapes having through holes (notation is omitted). The terminal conductors 21 are inserted into the through holes. Further, the insulating portions 27 in which the terminal conductors 21 are inserted are fired. Due to this, the terminal parts 417 are prepared.

The insulating portions 27 before firing may be suitably shaped. For example, the insulating portions 27 may be shaped by a die having cores corresponding to the through holes. Further, for example, in the insulating portions 27, the outer shapes may be shaped by the die, then through holes may be formed by drilling or the like. Further, for example, the insulating portions 27 may be shaped by winding ceramic green sheets around core materials as well.

In a ease where the terminal parts 417 are prepared in this way, the insulating portions 27 may fasten the terminal conductors 21 by contraction of the ceramic at the time of firing.

For this purpose, the diameters of the through holes in the insulating portions 27 before firing are set to sizes which are equal to or greater than the diameters of the terminal conductors 21 and which become smaller than the diameters of the terminal conductors 21 by contraction by firing (when assuming no terminal conductors 21). The difference between the diameters of the terminal conductors 21 and the diameters of the through holes after contraction when assuming no terminal conductors 21 may be made for example 0.2 mm to 0.4 mm.

The terminal parts 417 may be prepared by a manufacturing method different from that described above. For example, the terminal parts 417 may be prepared by the hot press method by placing the terminal conductors 21 in the die for hot pressing the raw material powder of ceramic forming the insulating portions 27. Further, for example, the terminal parts 417 may be prepared by winding ceramic green sheets forming the insulating portions 27 around the terminal conductors 21 and firing the same as well. The ceramic forming the insulating portions 27 may be placed at the surroundings of the terminal conductors 21 by thermal spraying as well.

The insulating portions 27 may be fixed to the base body 13 by a suitable method. For example, the two may be fixed by inserting the terminal parts 417 after firing into the holes 13h provided in the base body 13 before firing and firing the base body 13 and terminal parts 417 together. Further, for example, the two may be fixed by inserting the terminal parts 417 after firing into the holes 13h in the base body 13 after firing and bonding the two as well.

Where fixing them together by firing, at least one of the terminal conductors 21 and the insulating portions 27 may be fastened by the base body 13 in the same way as the terminal conductors 21 in the first embodiment. For example, the diameters of first hole portions 13ha in the holes 13h, which correspond to the terminal conductors 21, may be set in the same way as the diameters of the holes 13h in the first embodiment. Further, for example, second hole portions 13hb corresponding to the insulating portions 27 in the holes 13h may have the diameters before firing being made sizes which are equal to or greater than the diameters of the insulating portions 27 and which become smaller than the diameters of the insulating portions 27 due to contraction by firing (when assuming no terminal conductor 21). The difference between the diameters of the insulating portions 27 and the diameters of the second hole portions 13hb after contraction when assuming no insulating portions 27 may be made for example 0.2 mm to 0.4 mm.

Further, when the base body 13 after firing and the insulating portions 27 after firing are joined, they may be joined by a suitable method. For example, the base body 13 and the insulating portions 27 may be joined by an adhesive interposed foe tween the two or joined by solid phase bonding without an adhesive interposed between the two. The solid phase bonding is as explained in the explanation of the bonding between the base body 13 and the pipe 11.

When insulating portions 27 and the base body 13 are fixed together by firing or solid phase bonding after firing, the ceramic particles in the two are adhered to each other. Further, depending on materials of the insulating portions 27 and the base body 13, the boundaries of the two become obscure or disappear.

As explained above, in the present embodiment as well, the lower surface 13b of the base body 13 has the inclined surfaces 13baa reaching the terminal parts 417. Accordingly, for example, the same effects as those by the first embodiment are exhibited. Specifically, for example, the heat transferred from the resistance heating element 15 through the terminal parts 417 to the projecting portions 13e becomes easier to be transferred to the upper part.

Further, in the present embodiment, the terminal parts 417 have the insulating portions 27 and terminal conductors 21. The insulating portions 27 are buried at least partially in the base body 13 and are exposed from the lower surface 13b of the base body 13. The terminal conductors 21 are at least partially positioned in the base body 13 and pass through the insulating portions 27 to thereby be exposed from the lower surface of the insulating portions 27 to the exterior of the base body 13. The adjacent regions 13ba are adjacent to the insulating portions 27 and surround the insulating portions 27.

Mechanical stress accompanying vibration of the apparatus is applied to the ceramic structure (heater 1 in the present embodiment). As vibration, for example, there can be mentioned mechanical vibration accompanying injection of gas or exchange of wafers Wf or very small vibration accompanying electromagnetism/high frequency etc. If the terminal conductors 21 vibrate for a long period of time due to such vibration, there is a possibility of formation of cracks in the base body 13, particularly the portions in the lower surface 13b contacting the terminal conductors 21, or the terminal conductors 21 themselves. By burying the terminal conductors 21 in the insulating portion 27, for example, movement of the terminal conductors 21 is restricted, so the probability of formation of cracks in the base body 13 or terminal conductors 21 can be lowered.

Further, in the present embodiment, the insulating portions 27 are made of ceramic, and the base body 13 and the insulating portions 27 are fixed by adhesion of their ceramic particles to each other. In other words, they are bonded by firing and solid phase bonding. Accordingly, for example, the two can be strongly bonded. Further, for example, due to the increased density of the ceramic, bubbles between the base body 13 and the insulating portions 27 are reduced, therefore the heat which escaped from the terminal conductors 21 to the insulating portions 27 becomes easier to be transferred to the base body 13.

### Fifth Embodiment

FIG. 7 is a view showing the configuration of a principal part in a heater 501 according to a fifth embodiment and corresponds to FIG. 3 for the first embodiment (however, illustration of the wiring members 7 is omitted).

The heater 501, in short, is configured as the shape of the lower surface 13b in the second embodiment (FIG. 4) and the terminal parts 417 in the fourth embodiment (FIG. 6) combined. That is, the projecting portions 13e project from the recessed portions 13f. The projecting portions 13e (adjacent regions 13ba) are contiguous with the insulating portions 27 of the terminal parts 417.

Note that, as explained in the explanation of the fourth embodiment, even in the case where use is made of terminal parts 417 having different diameters from the terminal parts 17, the dimensions of the adjacent regions 13ba, the inclined surface 13baa (projecting portions 13e) and the like illustrated in the first embodiment may be applied to the present embodiment by replacing the terminal parts 17 with the terminal parts 417. In the same way, the dimensions of the recessed portions 13f explained in the second embodiment may be applied to the present embodiment.

In the present embodiment as well, due to provision of the inclined surfaces 13baa, the effects explained in the first, second, and/or fourth embodiments are exhibited. For example, the heat transferred from the terminal parts 417 to the base body 13 becomes easier to be transferred to the upper part. Further, it becomes easy to restrict vibration of the terminal conductors 21.

### Sixth Embodiment

FIG. 8 is a view showing the configuration of a principal part in a heater 601 according to a sixth embodiment and corresponds to FIG. 3 for the first embodiment (however, illustration of the wiring members 7 is omitted).

The heater 601, in short, is configured as a shape eliminating the recessed portions 13f from the lower surface 13b in the third embodiment (FIG. 5) and the terminal parts 417 in the fourth embodiment (FIG. 6) combined. That is, the inclined surfaces 13baa configure the chamfered surfaces for the surrounding region there, main region 13bb) and the inner surfaces of the holes 13h (in more detail, the second hole portions 13hb). The inclined surfaces 13baa (adjacent regions 13ba) are contiguous with the insulating portions 27 of the terminal parts 417.

Note that, as explained in the explanation of the third embodiment, unlike the example shown in FIG. 5, the recessed portions 13f need not be provided. On the other hand, in the sixth embodiment, unlike the example shown in FIG. 8, the recessed portions 13f may be provided. As explained in the explanation of the third embodiment, for the dimensions of the adjacent regions 13ba, inclined surfaces 13baa and the like, the explanations of the first and second embodiments can be employed by inverting the top and the bottom. Even in the present embodiment having the terminal parts 417 which are different in the diameters from the terminal parts 17 in the third embodiment, the explanations of the first and second embodiments can be employed by inverting the top and the bottom and replacing the terminal parts 17 with the terminal parts 417.

In the present embodiment as well, due to provision of the inclined surfaces 13baa and the like, the effects explained in the first, third, and/or fourth embodiments are exhibited. For example, stress caused by the loads which are applied from the terminal parts 417 to the inner surfaces of the holes 13h in the horizontal direction becomes harder to concentrate at the lower edge parts of the holes 13h. Further, vibration of the terminal conductors 21 is restricted by the insulating portions 27, therefore the stress generated in the edge parts in the lower part can be further reduced.

### Seventh Embodiment

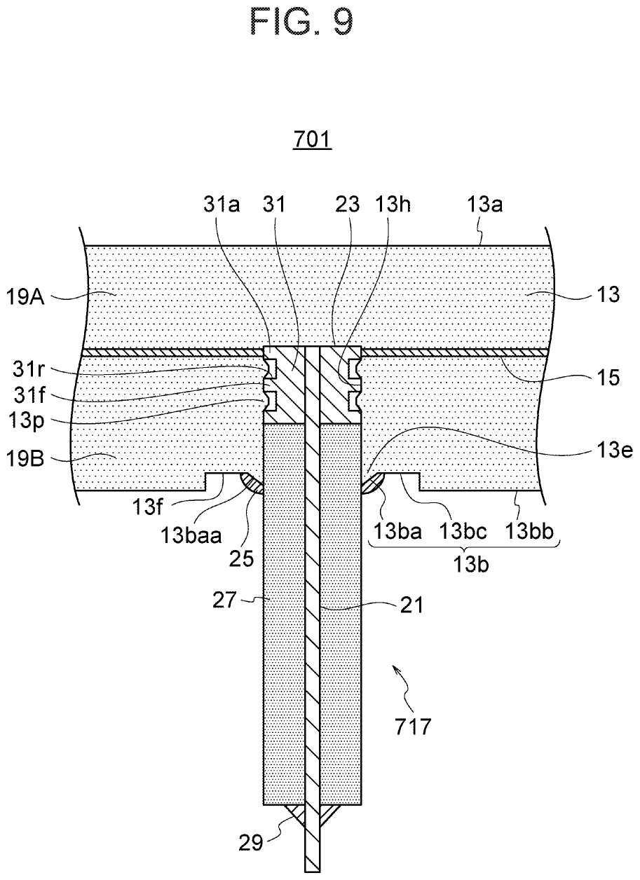

FIG. 9 is a view showing the configuration of a principal part in a heater 701 according to a seventh embodiment and corresponds to FIG. 3 for the first embodiment (however, illustration of the wiring members 7 is omitted).

The heater 701 differs in the configuration of the terminal parts 717 from the configurations of the terminal parts in the other embodiments. Note that, in the example shown, as the configuration of the lower surface 13b of the base body 13, ones in the second and fifth embodiments (FIG. 4 and FIG. 7) are illustrated. However, the terminal parts 717 in the present embodiment may be combined with the configuration of the lower surface 13b in the first, third, fourth, or sixth embodiments (FIG. 3, FIG. 5, FIG. 6, or FIG. 8) as well.

The terminal parts 717, in short, are configured as the terminal parts 417 in the fourth embodiment to which the connection conductors 31 are added. The connection conductors 31 are the portions in the terminal parts 717 connected (joined) with the internal conductor (resistance heating element 15). From the connection conductors 31, the terminal conductors 21 extend downward and extend outward to the exterior of the base body 13 (are exposed). Due to this, the terminal parts 717 become able to conductively connect the resistance heating element 15 and the exterior of the base body 13.

The shapes and dimensions of the connection conductors 31 may be suitably set. For example, the connection conductors 31 may be block-shaped as in the example shown. Otherwise, unlike the example shown, they may be plate shaped or rod shaped. Further, the shapes of the connection conductors 31 may be a substantially right angle column shapes, conical shapes, or frustum shapes. Further, for example, the shapes when viewed on a plane may be circular, polygonal, or other suitable shapes. In the connection conductors 31, any of the sizes in the vertical direction and the diameters (maximum diameters or minimum diameters) when viewed on a plane may be larger as well.

The connection conductors 31, for example, are connected at their side surfaces to the resistance heating element 15 by projecting higher than the resistance heating element 15. However, unlike the example shown, the connection conductors 31 may be connected at their upper surfaces with the resistance heating element 15 by positioning the upper surfaces at substantially the same heights as the resistance heating element 15. In the connection conductors 31, the parts which are connected with the resistance heating element 15 (upper ends and/or portions at any positions in the vertical direction in the connection conductors 31) will be called as the “connection portions 31a”. The connection portions 31a may be connected to the resistance heating element 15 by for example the two directly abutting against each other or through conductive bonding materials 23 in the same way as connections of the terminal conductors 21 with the resistance heating elements 15.

The connection portions 31a for example have diameters larger than the diameters of the terminal conductors 21 when viewed on a plane and/or the connection portions 31a have sizes large enough so that the entireties of the transverse cross-sections of the terminal conductors 21 fall in the inner sides from the outer edges of the connection portions 31a. When the transverse cross-sections of the connection portions 31a and terminal conductors 21 are not circular, in comparison of the diameters of the two, for example, use may be made of diameters in directions where the connection portions 31a and the resistance heating element 15 are connected to each other when viewed on a plane. In a case where the connection portions 31a are connected to the resistance heating element 15 over their entire circumferences when viewed on a plane, for example, the maximum diameters of the connection portions 31a and the maximum diameters of the terminal conductors 21 may be compared. Further, when the transverse cross-sections of the terminal conductors 21 are not constant in the long direction of the terminal conductors 21, as the diameters or transverse cross-sections of the terminal conductors 21 used for comparison described above, for example, use may be made of the largest portions in the terminal conductors 21 among the portions positioned inside the base body 13.

The diameters of the connection portions 31a may be suitably set. For example, the diameters of the insulating portions 27 illustrated in the fourth embodiment may be employed for the diameters of the connection portions 31a. When employing the above, the diameters of the connection portions 31a may be the same as or may be different from the diameters of the insulating portions 27.

Further, the diameters of the portions other than the connection portions 31a in the connection conductors 31 may be smaller than, equal to, or larger than the diameters of the terminal conductors 21. However, in the example shown, the terminal conductors 21 are inserted into the connection conductors 31, therefore the diameters of the connection conductors 31 are larger than the diameters of the terminal conductors 21.

The lengths of the connection conductors 31 or connection portions 31a in the vertical direction may be made for example the thickness of the resistance heating element 15 (length in the vertical direction) or more. Further, for example, the lengths of the connection conductors 31 in the vertical direction may be made 1/20 or more, 1/10 or more, ⅓ or more, or ½ or more relative to the thickness of the base body 13 from the resistance heating element 15 up to the lower surface 13b of the base body 13. The lower surface 13b referred to here may be any of the adjacent regions 13ba, main region 13bb, and intermediate regions 13bc.

Further, for example, the lengths of the connections conductors 31 in the vertical direction are set so that the connection conductors 31 do not project from the adjacent regions 13ba in the present embodiment (an aspect where the adjacent regions 13ba are contiguous with the insulating portions 27). For example, the lengths of the connection conductors 31 in the vertical direction may be made 19/20 or less, 9/10 or less, ⅔ or less, ⅓ or less, or ⅕ or less relative to the thickness of the base body 13 from the resistance heating element 15 up to the lower surface 13b of the base body 13. The lower surface 13b referred to here may be any of the adjacent regions 13ba, main region 13bb, and intermediate regions 13bc. Depending on the amounts of projection of the connection conductors 31 higher than the resistance heating element 15, it is also possible to set the lengths of the connection conductors 31 in the vertical direction to not less than the thickness of the base body 13 from the resistance heating element 15 to the adjacent regions 13ba. The above lower limits and upper limits concerning the lengths of the connection conductors 31 in the vertical direction may be suitably combined unless they are contradictory.

In the example shown, the connection conductors 31 are shaped as right angle columns with recessed retracted portions 31r formed in the side surfaces (outer circumferential surfaces). From another viewpoint, if based on the bottom surfaces of the retracted portions 31r, the connection conductors 31 have projecting portions 31f which project to the lateral sides at the surroundings of the retracted portions 31r (for example above or below the retracted portions 31r). Note that, the shapes of the right angle columns when viewed on a plane may toe made suitable shapes as already explained. Further, it is also possible to provide the retracted portions 31r on the side surfaces of a block shape other than a right angle column.

The number, shapes, and dimensions of the retracted portions 31r (projecting portions 31f) may be suitably set. For example, only one refracted portion 31r may be provided or two or more of them may toe provided. Further, in a case where two or more retracted portions 31r are provided, they may have mutually the same shapes or may have mutually different shapes. The plurality of retracted portions 31r may be arranged or distributed in the vertical direction and/or horizontal direction or another suitable direction. The pitch of arrangement or density of distribution may be equal or uniform or may toe biased in any direction.

Further, for example, when viewing the outer circumferential surfaces of the connection conductors 31 in their normal direction (when viewing the outer circumferential surfaces laid out in a plane shape), the retracted portions 31r may have shapes extending in groove shapes or may have shapes where the lengths in the directions perpendicular to each other are not extremely different (for example circular or polygonal shapes which are generally assumed). The groove-shaped retracted portions 31r for example may extend in the horizontal direction or may spirally extend like thread grooves. Further, in the retracted portions 31r, the shapes of the transverse cross-sections perpendicular to the normal direction may be constant relative to the position in the depth direction of the retracted portions 31r or may change according to the position in the depth direction.

Further, for example, the lengths of the retracted portions 31r in the vertical direction (thickness direction of the base body 13) in the case where retracted portions 31r are provided at only one position in the vertical direction, or the totals of the lengths in the vertical direction of the plurality of retracted portions 31r in the case where retracted portions 31r are provided at a plurality of positions, may be made for example 1/50 or more, 1/10 or more, ⅕ or more, ⅓ or more, or ½ or more relative to the lengths of the connection conductors 31 in the vertical direction. Further, the above lengths or the above totals of lengths of the retracted portions 31r may be made 9/10 or less, ⅔ or less, ½ or less, or ⅕ or less relative to the lengths of the connection conductors 31. The lower limits and the upper limits described above may be suitably combined unless they are contradictory. Further, the lengths of the retracted portions 31r in the vertical direction may be made for example 0.1 mm or more.

In the example shown, retracted portions 31r are provided at two positions in the vertical direction. At each position, the retracted portion 31r for example extends so as to surround the connection conductor 31 when viewed on a plane. That is, the retracted portions 31r are configured by recessed grooves which surround the connection conductors 31, while the projecting portions 31f are configured by ridges or flanges. Otherwise, at each position, when viewed on a plane, a plurality of retracted portions 31r are arranged so as to surround the connection conductors 31. In this case, at one position in the vertical direction, the number of the plurality of retracted portions 31r and intervals of the same may be suitably set. For example, at one position in the vertical direction, the number of the plurality of retracted portions 31r is three or more, and the plurality of retracted portions 31r may be arranged so that the angular interval among the retracted portions 31r becomes 120° or less on the plan view. The retracted portions 31r formed by surrounding recessed grooves or plurality of retracted portions 31r which are arranged so as to surround the connection conductors may be provided at a suitable number of positions in the vertical direction. For example, these may be provided at one to three positions.

The material of the connection conductors 31 may be made a suitable material. It may be the same as or may be different from the material of the internal conductor (resistance heating element 15) and/or the material of the terminal conductors 21.

When viewed on a plane, the connection conductors 31 and the insulating portions 27 (at least the portions buried in the base body 13) are for example given the same shapes and sizes as each other. The shapes and sizes referred to here are shapes and sizes obtained by projecting the connection conductors 31 and insulating portions 27 in the vertical direction and/or the shapes and sizes of the maximum transverse cross-sections of the connection conductors 31 and insulating portions 27.

The transverse cross-sections of the holes 13h in the base body 13 in which the connection conductors 31 and insulating portions 27 are inserted are substantially constant with respect to the vertical direction. That is, the holes 13h have the same transverse cross-sections (diameters) over the connection conductors 31 and the insulating portions 27. However, the holes 13h may be made larger in the diameters of the portions in which the insulating portions 27 are inserted than the diameters of the portions in which the connection conductors 31 are inserted.

On the inner surfaces of the holes 13h, regions facing the retracted portions 31r project into the retracted portions 31r and configure penetrating portions 13p. The shapes and sizes of the penetrating portions 13p may be made suitable shape. In the example shown, the penetrating portions 13p are formed in tapered shapes. Further, there are spaces between the penetrating portions 13p and the inner surfaces of the retracted portions 31r. The spaces may be sealed with a suitable gas or may be evacuated (state reduced in pressure more than the atmospheric air). Further, unlike the example shown, the penetrating portions 13p may substantially fill the retracted portions 31r as well.

The terminal conductors 21 differ from the terminal conductors 21 in the other embodiments only in the point that they are connected to the connection conductors 31 in place of the resistance heating element 15. The terminal conductors 21 and the connection conductors 31 may be connected by a suitable method. In the example shown, the terminal conductors 21 are inserted in holes (notation is omitted) provided in the connection conductors 31. Due to this, they are connected to the connection conductors 31. Note that, unlike the example shown, holes need not be provided in the connection conductors 31. The lower surfaces of the connection conductors 31 and the upper parts of the terminal conductors 21 may be joined, or the connection conductors 31 and the terminal conductors 21 may be integrally formed from the same material.

In the case where the terminal conductors 21 are inserted in the connection conductors 31 as described above, the holes in the connection conductors 31 may be through holes (example shown) or may be blind holes (recessed portions) which are opened downward. Further, the upper surfaces of the terminal conductors 21 may be flush with the upper surfaces of the connection conductors 31 (example shown), may be positioned higher than the upper surfaces of the connection conductors 31, or may be positioned lower than the upper surfaces of the connection conductors 31 (in this case, the holes in the connection conductors 31 may be through holes or may be blind).

Further, the outer surfaces of the terminal conductors 21 and the inner surfaces of the holes in the connection conductors 31 may be suitably connected. For example, male screws may be formed in the terminal conductors 21, female screws may be formed in the connection conductors 31, and the two may be screwed together. Further, for example, the terminal conductors 21 and the connection conductors 31 may simply abut against each other. In this case, crimping may be carried out. Further, for example, the terminal conductors 21 and the connection conductors 31 may be joined by conductive bonding materials interposed between the two as well.

The heater 701, in the same way as the other embodiments, may be prepared by insertion of previously prepared terminal parts 717 into the holes 13h in the base body 13 before firing or after firing. In a case where the terminal parts 717 are inserted into the holes 13h in the ceramic green sheets forming the base body 13 and firing the same, the connection conductors 31 may be fastened by the base body 13 by contraction of the base body 13 by firing in the same way as the insulating portions 27. At this contraction, the regions in the inner surfaces of the holes 13h which face the retracted portions 31r are pushed into the retracted portions 31r. Due to this, the penetrating portions 13p are formed. When the connection conductors 31 are fastened by the base body 13 in this way, the diameters of the holes 13h before firing are for example set to sizes which are equal to or greater than the diameters of the connection conductors 31 and which become smaller than the diameters of the connection conductors 31 due to contraction by firing (when assuming no connection conductors 31). The difference between the diameters of the connection conductors 31 and the diameters of the holes 13h after contraction when assuming no connection conductors 31 may be made for example 0.2 mm to 0.4 mm.

Further, the heater 701, in the same way as the other embodiments, may be prepared by the hot press method. In this case, raw material powder of ceramic forming the base body 13 is filled in the refracted portions 31r, whereby penetrating portions 13p having shapes filled in the retracted portions 31r are formed.

In the present embodiment as well, by provision of the inclined surfaces 13baa, the same effects as those by the other embodiments are exhibited.

Further, in the present embodiment, the terminal parts 717 have the connection conductors 31 and the terminal conductors 21. The connection conductors 31 are at least partially positioned inside the base body 13 and are connected to the internal conductor (resistance heating element 15). The terminal conductors 21 are smaller in diameters than the connection conductors 31 when viewing the base body 13 on a plane, are electrically connected through the connection conductors 31 with the resistance heating element 15, and are at least partially positioned lower than the connection conductors 31.

In this case, for example, compared with the case where the terminal conductors 21 are made to contact the resistance heating element 15, it is easier to secure the contact areas between the terminal parts and the resistance heating element 15. Further, compared with a case where the diameters of the terminal conductors 21 are made large in an aspect where the terminal conductors 21 contact the resistance heating element 15, the volumes of the conductors inside the terminal parts can be made smaller in the vicinity of the lower surface 13b of the base body 13. As a result, for example, the stress which is applied to the vicinity of the lower surface 13b of the base body 13 when the conductors in the terminal parts expand can be reduced. The vicinity of the lower surface 13b easily becomes the starting point of cracking, therefore the probability of occurrence of cracks can be lowered. Further, for example, the heat which escapes from the resistance heating element 15 through the conductors in the terminal parts to the exterior or transferred through the conductors in the terminal parts to the lower part in the base body 13 is reduced, therefore the upper surface 13a of the base body 13 can be efficiently heated.

Further, in the present embodiment, the base body 13 has the holes 13h which are opened at the lower surface 13b and in which the terminal parts 717 are inserted. The connection conductors 31 have the recessed retracted portions 31r in the outer circumferential surfaces surrounded by the inner surfaces of the holes 13h.

In this case, for example, it is possible to make the penetrating portions 13p entering into the retracted portions 31r engage with the connection conductors 31 (projecting portions 31f) and make the probability of the terminal parts 717 dropping out from the base body 13 lower. Further, for example, in a case where spaces are formed in the retracted portions 31r, the contact areas between the portions in the base body 13 on the lower side than the resistance heating element 15 and the connection conductors 31 are reduced, and the heat transferred from the resistance heating element 15 through the connection conductors 31 to the lower part of the base body 13 is reduced, thus the upper surface 13a of the base body 13 can be efficiently heated.

### Eighth Embodiment

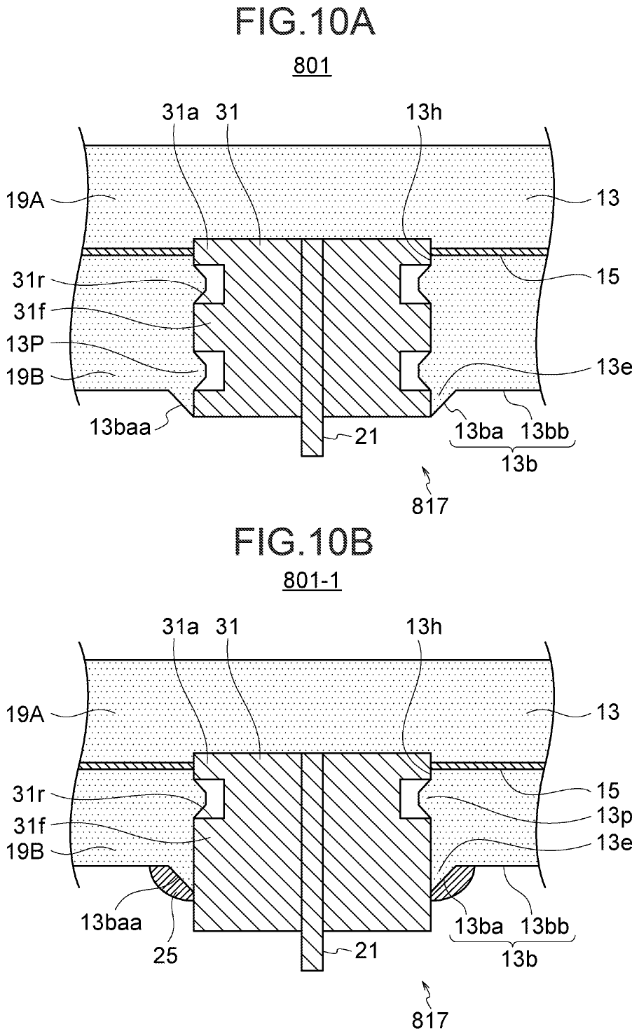

FIG. 10A is a view showing the configuration of a principal part in a heater 801 according to an eighth embodiment and corresponds to FIG. 3 for the first embodiment (however, illustration of the wiring members 7 is omitted).

The heater 801, in short, is configured as the seventh embodiment (FIG. 9) eliminating the insulating portions 27 from the terminal parts 717 and making the connection conductors 31 contact the adjacent regions 13ba (inclined surfaces 13baa). Note that, in the example shown, as the configuration of the lower surface 13b of the base body 13, one in the first and fourth embodiments (FIG. 3 and FIG. 6) is illustrated. However, the terminal parts 817 in the present embodiment may be combined with the configuration of the lower surface 13b in the second, third, or fifth to seventh embodiments (FIG. 4, FIG. 5, or FIG. 7 to FIG. 9) as well.

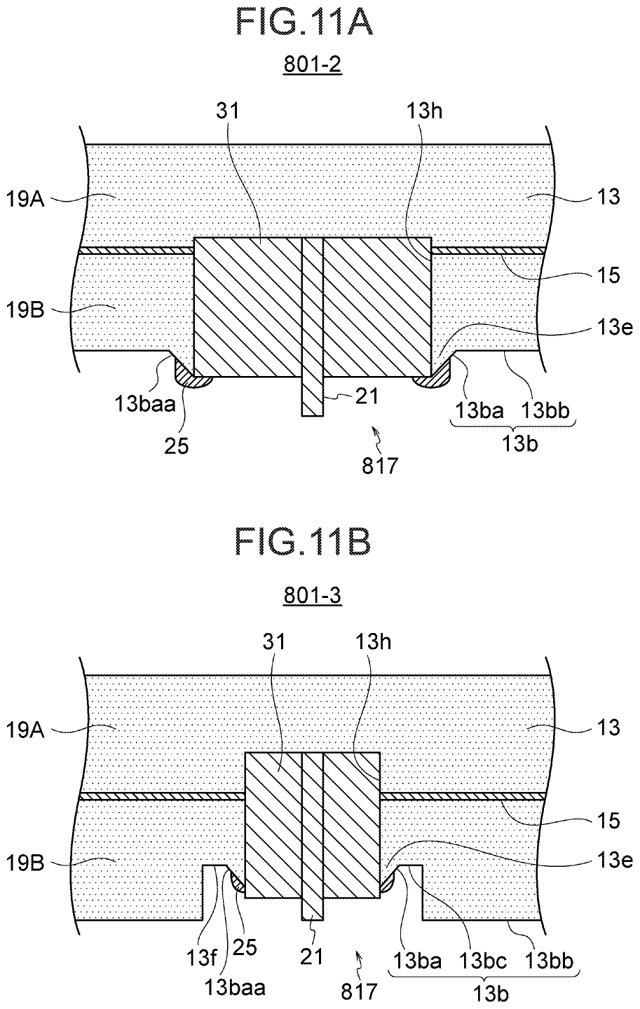

FIG. 10B is a view which shows a heater 801-1 according to a first modification of the eighth embodiment and is the same drawing as FIG. 10A. FIG. 11A is a view which shows a heater 801-2 according to a second modification of the eighth embodiment and is the same drawing as FIG. 10A. FIG. 11B is a view which shows a heater 801-3 according to a third modification of the eighth embodiment and is the same drawing as FIG. 10A.

As understood from FIG. 10A to FIG. 11B, the positions where the adjacent regions 13ba and the side surfaces of the connection conductors 31 are contiguous may be the lower ends of the side surfaces of the connection conductors 31 or may be the middles of the side surfaces of the connection conductors 31. Further, the retracted portions 31r may be provided or may not be provided. The configuration of the lower surface 13b may be any of those in the first to seventh embodiments.

In the present embodiment and its modifications, the lengths of the connection conductors 31 in the vertical direction may be suitably set so far as the positions of the lower surfaces of the connection conductors 31 in the vertical direction are positioned so as to be equal to or lower than the positions of the adjacent regions 13ba in the vertical direction. Further, there is no particular upper limit on the lengths of the connection conductors 31 in the vertical direction. However, for example, they may be made 1.5 times or less or 3 times or less of the thickness of the base body 13 from the resistance heating element 15 up to the lower surface 13b of the base body 13.

In the present embodiment as well, by provision of the inclined surfaces 13baa, the same effects as those by the other embodiments are exhibited.

Further, in the present embodiment, the terminal parts 817, in the same way as the terminal parts 717 in the seventh embodiment (FIG. 9), have the connection conductors 31 and the terminal conductors 21. However, in the terminal parts 817, the adjacent regions 13ba (inclined surfaces 13baa) are adjacent to the connection conductors 31 and surround the connection conductors 31.

In this case, for example, compared with the case where the terminal conductors 21 are contiguous with the adjacent regions 13ba, the contact areas between the terminal parts 817 and the base body 13 are made large, and thus the bonding strength can be improved. Further, for example, compared with the seventh embodiment, the configuration is simpler since no insulating portions 27 are provided.

### Ninth Embodiment

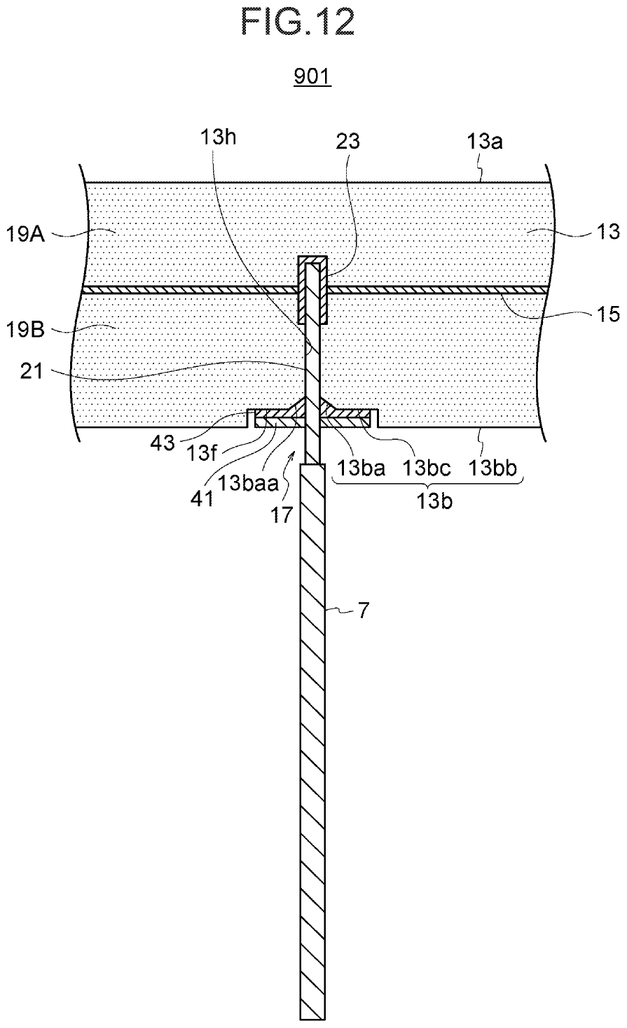

FIG. 12 is a view showing the configuration of a principal part in a heater 901 according to a ninth embodiment and corresponds to FIG. 3 for the first embodiment.

The heater 901, in short, is configured as the third embodiment (FIG. 5) in which lid bodies 41 covering the lower surface 13b of the base body 13 from the lower part and sealing materials 43 which are interposed between the lower surface 13b and the lid bodies 41 and are adhered to the two are added. The terminal parts 17 (in more detail, the terminal conductors 21) pass through the sealing material 43 and the lid bodies 41 and extend outward to lower than the lid bodies 41.

The shapes and sizes etc. of the lid bodies 41 may foe suitably set. In the example shown, the lid bodies 41 are flat plate shapes having sizes large enough to be accommodated in recessed portions 13f which are formed in the lower surface 13b of the base body 13. Their planar shapes are for example substantially the same as the shapes of the outer edges of the recessed portions 13f. The thicknesses of the lid bodies 41 are for example somewhat smaller than the depths of the recessed portions 13f. The lid bodies 41 face the adjacent regions 13ba and intermediate regions 13bc in the lower surface 13b. In other words, the lid bodies 41 face at least the adjacent regions 13ba.

The material of the lid bodies 41 may be made for example any insulation material. For example, the material of the lid bodies 41 is ceramic. The ceramic may be the same as the ceramic configuring the base body 13 or may be a different one. In the latter case, the lid bodies 41 and the base body 13 may be the same in the principal constituents or may be different in the principal constituents. Specific examples of ceramic are as explained in the explanation of the base body 13. It is for example aluminum nitride.

The sealing materials 43, by adhesion to the base body 13 and lid bodies 41, for example, contribute to bonding of the two and/or contribute to improvement of sealability of the holes 13h in which the terminal conductors 21 are inserted. The ranges where the sealing materials 43 are arranged may be suitably set. In the example shown, the sealing materials 43 are arranged over substantially the entireties of the upper surfaces of the lid bodies 41. From another viewpoint, the sealing materials 43 are arranged covering the adjacent regions 13ba and intermediate regions 13bc. In other words, the sealing materials 43 are adhered to at least the adjacent regions 13ba. Although not particularly shown, the sealing materials 43, for example, in addition to the illustrated arrangement range, may be interposed between the outer circumferential surfaces of the lid bodies 41 and the inner circumferential surfaces of the recessed portions 13f as well. The material of the sealing materials 43 may be made a suitable one. For example, use may be made of one explained as the material of the already explained sealing materials 25 (FIG. 6) and the like (for example AlCaY bonding agent).

As explained above, in the present embodiment, the heater 901 has the insulating lid bodies 41 and insulating sealing materials 43. The terminal conductors 21 are inserted in the lid bodies 41. The lid bodies 41 cover the adjacent regions 13ba from the lower parts. The sealing materials 43 are interposed between the adjacent regions 13ba and the lid bodies 41 and are adhered to the two.

Accordingly, for example, when the terminal conductors 21 having a larger linear expansion coefficient than the linear expansion coefficients of the base body 13, sealing materials 43, and lid bodies 41 expand due to heat, the stress which is applied to the base body 13 at the surroundings of the terminal conductors 21 is dispersed to the sealing materials 43 and lid bodies 41. As a result, for example, the probability of occurrence of cracks in the base body 13 can be reduced.

Note that, in the example shown, the lid bodies 41 and sealing materials 43 were provided with respect to the third embodiment. However, the lid bodies 41 and sealing materials 43 may be applied to the other embodiments (for example first and second embodiments) as well.

### 10th Embodiment

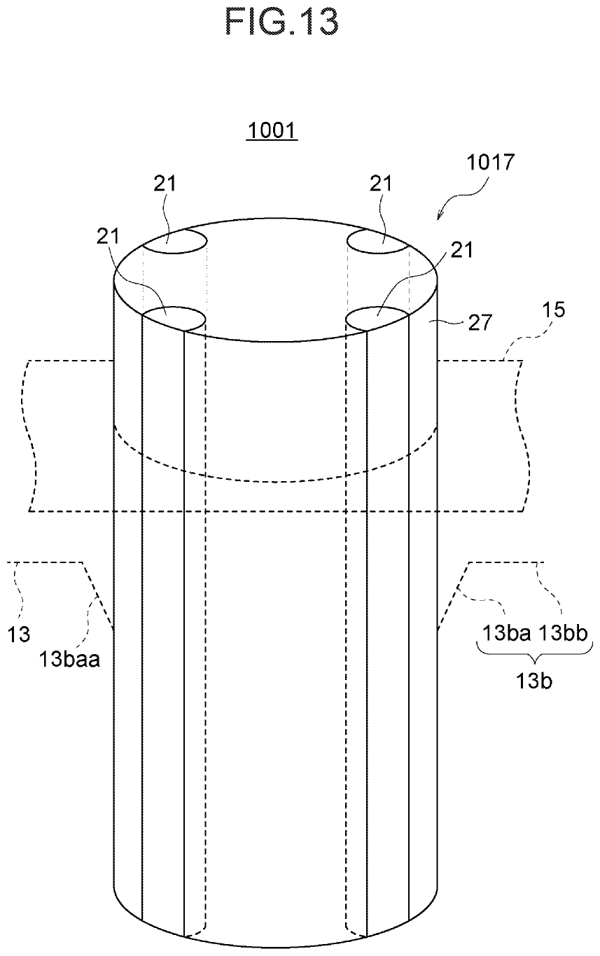

FIG. 13 is a view showing the configuration of a principal part in a heater 1001 according to a 10th embodiment. In more detail, FIG. 13 is a perspective view of a terminal part 1017 in the heater 1001.

The fourth embodiment (FIG. 6) showed the terminal parts 417 having the terminal conductors 21 inserted in the insulating portions 27. In the terminal parts 417, the terminal conductors 21 pass through the insulating portions 27 in the state with the outer circumferential surfaces of the terminal conductors 21 covered by the insulating portions 27 over their entire circumferences. On the other hand, in the present embodiment, the terminal conductors 21 pass through the insulating portions 27 in a state where parts of the outer circumferential surfaces of the terminal conductors 21 are exposed from the outer circumferential surfaces of the insulating portions 27.

The number and arrangement of the terminal conductors 21 may be suitably set. In the example shown, a plurality of (four) terminal conductors 21 are arranged along the outer circumference of the insulating portions 27. Note that, unlike the example shown, only one terminal conductor 21 need be provided with respect to one insulating portion 27 as well. Further, in the example shown, the interval of arrangement of the plurality of terminal conductors 21 is for example constant. From another viewpoint, the arrangement of “n” number of terminal conductors 21 is made an n-fold symmetrical (rotation symmetrical) arrangement.

Also, the shapes and sizes of the insulating portions 27 and terminal conductors 21 may be suitably set. In the example shown, the shapes of the insulating portions 27 are made substantially circular cylinder shapes. The shapes of the terminal conductors 21 are shaft shaped so as to extend parallel to the axes of the insulating portions 27. The shapes of the transverse cross-sections (horizontal surfaces) of the same are made substantially predetermined shapes (circles in the example shown) from which parts of the outer sides are removed at the boundaries of line segments (arcs in the example shown) along the outer circumferential surfaces of the insulating portions 27. In the outer circumferential surfaces of the terminal conductors 21, regions exposed from the outer circumferential surfaces of the insulating portions 27, while not particularly shown, may project somewhat to the outer side from the outer circumferential surfaces of the insulating portions 27.

In the example shown, the terminal parts 1017 pass through the resistance heating element 15. The plurality of terminal conductors 21 are connected to the resistance heating element 15 in regions in their outer circumferential surfaces which are exposed from the outer circumferential surfaces of the insulating portions 27. However, the terminal conductors 21 may also be connected at their upper surfaces to the lower surface of the resistance heating element 15. Note that, the terminal parts 1017 may be designed larger than the example shown, and the plurality of terminal conductors 21 may be formed as terminals respectively given different potentials and connected to mutually different resistance heating elements 15 and/or mutually different portions in the resistance heating element 15.

The terminal parts 1017, in the same way as the terminal parts in the other embodiments, have at least parts positioned inside the base body 13 and are exposed from the lower surface 13b of the base body 13 to the exterior. Further, adjacent regions 13ba (inclined surfaces 13baa) of the lower surface 13b surround the terminal parts 1017 and reach (adjoin) the terminal parts 1017. Note that, in FIG. 13, as the configuration of the lower surface 13b, the configuration of the lower surface 13b shown in the first embodiment is illustrated. However, the configuration of the lower surface 13b (and the configurations of the sealing materials etc.) may be made the configurations in the other embodiments (for example the lower surfaces 13b in the second to sixth embodiments) as well.

The method for manufacturing the terminal parts 1017 may be made the same as that of the terminal parts 417 in the fourth embodiment. For example, the terminal parts 1017 may be prepared by forming shaped articles of ceramic serving as the insulating portions 27, inserting the terminal conductors 21 into through holes in this shaped articles, and firing the results. Further, the terminal conductors 21 may be exposed from the outer circumferential surfaces of the insulating portion 27 by a suitable method. For example, in the shaped articles forming the insulating portions 27, through holes into which the terminal conductors 21 are inserted may be formed on the inner sides from the outer circumferential surfaces of the shaped articles. The terminal conductors 21 may be exposed from the outer circumferential surfaces of the insulating portions 27 by grinding the outer circumferential surfaces of the insulating portions 27 after firing. At this time, by also grinding the terminal conductors 21 together with the insulating portions 27, the terminal conductors 21 are shaped as circles from which parts are removed by arcs having larger radii than the circles. Naturally, the shapes of the shaped articles and the initial shapes of the terminal conductors 21 may be made the same as those after completion as well.

In the above configuration, for example, the same effects as those by the fourth embodiment are exhibited. For example, the terminal parts 1017 include the insulating portions 27, therefore the probability of occurrence of cracks in the lower surface 13b etc. in the base body 13 is reduced. Further, for example, in a case where the insulating portions 27 and the base body 13 are fixed by adhesion of the ceramic particles to each other, the bonding strength of the two is improved.

Further, in the present embodiment, the terminal conductors 21 pass through the insulating portions 27 in the states with parts of the outer circumferential surfaces of the terminal conductors exposed from the outer circumferential surfaces of the insulating portions 27. Accordingly, for example, conductive regions are secured on the outer circumferential surfaces of the terminal parts 1017 while the volumes of the conductors occupied in the terminal parts 1017 can be made small. As a result, for example, the difference of thermal expansion between the terminal parts 1017 and the base body 13 is reduced, thus the probability of occurrence of cracks in the base body 13 can be reduced. Note that, the terminal parts 417 in the fourth embodiment are for example simpler in configuration and/or method of preparation compared with the present embodiment,

[Modification of Terminal Conductors]

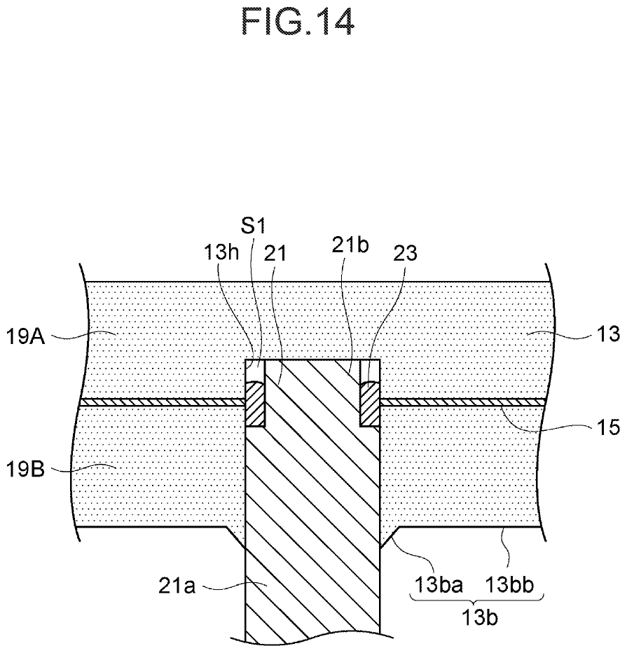

FIG. 14 is a cross-sectional view showing a terminal conductor 21-1 according to a modification and corresponds to a portion of the upper part in FIG. 3. Note that, here, as the overall configuration of the terminal part and the configuration of the lower surface 13b of the base body 13, those in the first embodiment (FIG. 3) are shown. However, the terminal conductor 21-1 may be applied to the other embodiments (for example second to sixth and ninth embodiments) as well.

The terminal conductors 21 shown in the explanations of the embodiments were made constant in the shapes of the transverse cross-sections perpendicular to the long directions over the long directions. On the other hand, the terminal conductor 21-1 according to the present modification is made smaller in the diameter of the front end (from another viewpoint, the area of the transverse cross-section) compared with the other portions. In other words, the terminal conductor 21-1 has a body portion 21a and a reduced-diameter portion 21b having a smaller diameter than the body portion 21a. The body portion 21a and reduced-diameter portion 21b are integrally formed by the same material.

The body portion 21a for example extends outward from the interior of the base body 13 to the exterior of the base body 13. In turn, the body portion 21a is surrounded by the adjacent region 13ba in the base body 13 and is adjacent to the latter. The body portion 21a, for example, may configure the entirety of the terminal conductor 21-1 other than the reduced-diameter portion 21b. The explanation of the terminal conductor 21 in the first embodiment may be applied to the body portion 21a excluding the explanation according to the connection with the resistance heating element 15.

The shape (excluding dimensions) of the transverse cross-section of the reduced-diameter portion 21b may be the same as (for example similar to) the shape of the transverse cross-section of the body portion 21a or may have quite a different shape. The reduced-diameter portion 21b may extend with a constant transverse cross-section or may be different in shape and/or diameter according to the position in the long direction. In the latter case, for example, a tapered shape making the diameter smaller toward the front end side can be mentioned. In such a case, steps between the reduced-diameter portion 21b and the body portion 21a may be removed as well. The difference between the diameter of the reduced-diameter portion 21b and the diameter of the body portion 21a and the length etc. of the reduced-diameter portion 21b may be suitably set.

A hole 13h in the base body 13 in which the terminal conductor 211 is inserted for example extends in the depth direction with substantially a constant transverse cross-section when contraction by firing is not considered or even if it is considered. Further, the transverse cross-section of the hole 13h for example has the same shape and dimensions as the shape and dimensions (diameter) of the transverse cross-section of the main body 21a. From another viewpoint, the transverse cross-section of the hole 13h is larger than the transverse cross-section of the reduced-diameter portion 21b. Accordingly, the inner circumferential surface of the hole 13h and the outer circumferential surface of the reduced-diameter portion 21b face each other across a gap.

In the gap, a conductive bonding material 23 is arranged. The bonding material 23 is interposed between the outer circumferential surface of the reduced-diameter portion 21b and the resistance heating element 15 exposed from the inner circumferential surface of the hole 13h and is adhered to the two and connects the two. The material of the bonding material 23 is as explained in the explanation of the first embodiment.

Accordingly, for example, as the material of the bonding material 23, use may be made of a composite material containing the same constituents as the material of the resistance heating element 15 and the same constituents as the material of the base body 13. Further, as the metal, use may be made of a constituent (for example platinum: Pt) different from the constituent of the material of the resistance heating element 15.

The amount of the bonding material 23 may be suitably set. For example, the amount of the bonding material 23, as in the illustrated example, may be an amount to be arranged at only part of the gap between the inner circumferential surface of the hole 13h and the outer circumferential surface of the reduced-diameter portion 21b. In other words, the gap may have a space S1. The space S1 contains a gas or is made a vacuum state. The space S1 is for example positioned higher than the resistance heating element 15. Further, the space S1, for example, as in the illustrated example, may extend from the outer circumferential surface of the reduced-diameter portion 21b up to the inner circumferential surface of the hole 13h. Further, the space S1, unlike the illustrated example, may be configured thinner than the gap from the outer circumferential surface of the reduced-diameter portion 21b up to the inner circumferential surface of the hole 13h by a bonding material 23 formed in a film on the outer circumferential surface of the reduced-diameter portion 21b or the inner circumferential surface of the hole 13h. Note that, unlike the illustrated example, the space S1 need not be configured either (the bonding material 23 may be filled in all of the gap as well).

As explained above, the terminal conductor 21-1 according to the modification has the reduced-diameter portion 21b which is smaller in diameter than the diameter of the body portion 21a and is connected (joined) with the resistance heating element 15. In this case, for example, as the entirety of the terminal conductor 21-1, the strength can be secured by the body portion 21a. On the other hand, in the connection position with the resistance heating element 15 (reduced-diameter portion 21b), the amount of the thermal expansion of the terminal conductor 21-1 in the diameter direction can be reduced. As a result, for example, even if heating by the heater is repeated, the probability of being to maintain the bonding of the resistance heating element 15 and the terminal conductor 21-1 is improved.

Further, in the illustrated modification, the space S1 is configured between the reduced-diameter portion 21b and the base body 13 (inner surface of the hole 13h). In this case, for example, even if the reduced-diameter portion 21b expands by heat, the force becomes harder to be transferred from the reduced-diameter portion 21b to the base body 13. As a result, for example, the probability of occurrence of cracks in the base body 13 can be reduced.

[One Example of Material of Heater]

As explained in the explanations of the first embodiment (FIG. 3) and fourth embodiment (FIG. 6), both of the material of the base body 13 in the heater plate 9 and the material of the insulating portions 27 in the terminal parts (for example 417) may be made ceramic. Further, the materials of the two (or their principal constituents) may be the same or may be different. Here, an example in a case where the material of the base body 13 and the material of the insulating portions 27 are ceramics which are the same in their entire constituents or in principal constituents.

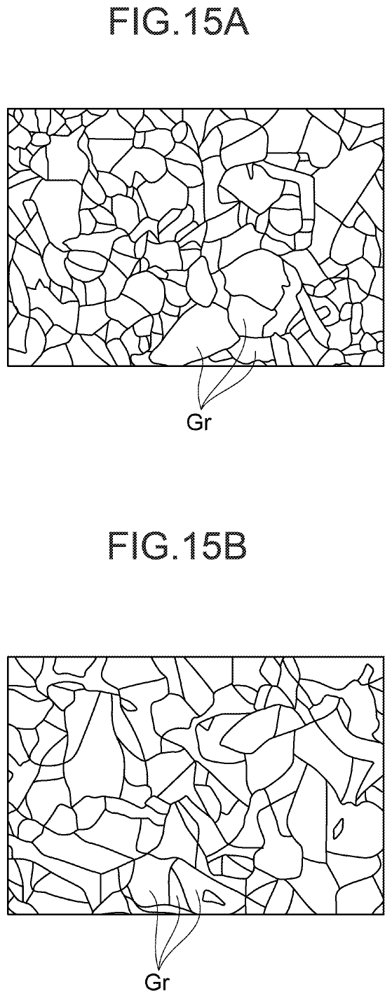

FIG. 15A is a cross-sectional view of a portion of the base body 13. FIG. 15B is a cross-sectional view of a portion of the insulating portion 27. These cross-sectional views show for example ranges where single sides become 50 μm to 200 μm. A plurality of grains Gr (single crystal grains, ceramic particles) are shown. From another viewpoint, the grain boundaries are shown.

As shown in these views, the mean value of crystal grain sizes (mean grain size) of the insulating portions 27 may be made larger than the mean value of crystal grain sizes in the base body 13. In this case, for example, the larger the crystal grain size of the ceramic, the larger the Young's modulus. Therefore, the strength of the insulating portions 27 can be made higher. As a result, for example, the probability of occurrence of cracks in the insulating portions 27 when a bending moment is applied to the insulating portions 27 can be reduced.

The constituents and mean grain size of the ceramic in such an aspect may be suitably set. For example, the principal constituent of the ceramic may be made aluminum nitride (AlN). The mean grain size in the base body 13 may be made for example 3 μm 1.5 to 8 μm. The mean grain size in the insulating portions 27 may be made for example 5 μm to 12 μm (however, larger than the mean grain size in the base body 13). The base body 13 and insulating portions 27 may include sintering aids which are the same or contain the same principal constituents. The element configuring the sintering aids may be made for example yttrium (Y).

Note that, the mean grain size may be measured by a suitable method. One example will be shown below. The mean of circle equivalent diameters of the crystals in the principal constituents (for example AlN) of the base body 13 and insulating portions 27 will be regarded as the mean grain sizes. The circle equivalent diameters are measured as follows. First, the cross-sections of the base body 13 and insulating portions 27 are machined to a mirror surface. The machined cross-sections are photographed by an SEM (scan electron microscope). The magnification at this time is made substantially 1000 times to 3000 times. Further, the projection area is made 1000 μm² to 20000 μm². Next, in the photographed image, profiles of the crystals of the principal constituents are traced by black lines. At this time, where sintering aids are contained, the crystals containing the sintering aids are colored black. The traced images are analyzed by using a procedure such as particle analysis of an image analyzing software “Azokun” (trademark, made by Asahi Kasei Engineering Corporation). By this analysis, the average circle equivalent diameters of the particles are obtained.

The method of making the mean grain size in the insulating portions 27 larger than the mean grain size in the base body 13 may be made a suitable one. For example, the number of times of firing the insulating portions 27 may be made larger than the number of times of firing the base body 13 and/or the time of firing the insulating portions 27 may be made longer than the time of firing the base body 13. Note that, the explanation of the fourth embodiment showed that the terminal parts 417 could be fixed to the base body 13 by inserting the terminal parts 417 after firing info the holes 13h in the base body 13 before firing and firing the two together. In this case, in contrast to the base body 13 which is only fired together with the insulating portions 27, the insulating portions 27 are fired solely as well before the firing together with the base body 13, therefore the grain size of the insulating portions 27 is apt to become larger than the grain size of the base body 13.

Note that, in the above embodiments and modifications, each of the heaters 1, 201, 301, 401, 501, 601, 701, 801, 801-1, 801-2, 801-3, 901, and 1001 is one example of the ceramic structure. The heater system 101 is one example of the wafer system. The resistance heating element 15 is one example of the internal conductor. Each of the intermediate regions 13bc in the third embodiment (FIG. 5) and ninth embodiment (FIG. 12) and the main region 13bb in the sixth embodiment (FIG. 8) is one example of the surrounding region. The main regions 13bb in the third embodiment (FIG. 5) and ninth embodiment (FIG. 12) are one example of the outer side region.

The heater according to the present disclosure is not limited to the above embodiments and may be worked in various ways.

In the embodiments, as the ceramic structure, ceramic heaters having heating functions were taken as examples. However, the ceramic structure may be one having another function as well. For example, the ceramic structure may be an electrostatic chuck or plasma generation-use structure, or may be one functioning as a combination of two or more of the electrostatic chuck, plasma generation-use structure and heater as well.

In other words, the internal conductor was a heating-use resistance heating element in the embodiments. However, the internal conductor may be a conductor for another purpose. For example, the internal conductor may be an electrostatic chuck-use electrode or plasma generation-use electrode. The ceramic structure may have one of these electrodes and a resistance heating element or a combination of two or more selected from among them. The internal conductor is for example a conductor which may have, in its entirety, a shape that extends along the upper surface of the base body (13) (faces the upper part). Further, for example, when assuming the minimum convex curve surrounding the entirety of the internal conductor when viewed on a plane, the region surrounded by the convex curve accounts for 60% or more or 80% or more of the upper surface of the base body.

### REFERENCE SIGNS LIST

1 . . . heater (ceramic structure), 13 . . . base body, 13a . . . upper surface, 13b . . . lower surface, 13ba . . . adjacent region, 13baa . . . inclined surface, 15, . . . resistance heating element (internal conductor), and 17 . . . terminal part.

1. A ceramic structure comprising:
a plate-shaped base body made of ceramic and comprising an upper surface on which a wafer is superimposed and a lower surface on an opposite side to the upper surface;
an internal conductor which is located inside the base body; and
a terminal part which is electrically connected to the internal conductor, is at least partially located inside the base body, and is exposed from the lower surface of the base body to an exterior of the base body, wherein
the lower surface of the base body comprises an adjacent region surrounding the terminal part, and
the adjacent region comprises an inclined surface in a portion reaching the terminal part.

2. The ceramic structure according to claim 1, wherein the inclined surface is located lower the closer to the terminal part and configures a projecting portion.

3. The ceramic structure according to claim 2, wherein
the lower surface of the base body comprises a recessed portion, and
the projecting portion projects inside the recessed portion.

4. The ceramic structure according to claim 1, wherein
the lower surface of the base body further comprises a surrounding region surrounding the adjacent region,
the base body comprises a hole which is opened at the lower surface and in which the terminal part is inserted, and
the inclined surface is located higher the closer to the terminal part and configures a chamfered surface obtained by chamfering a corner portion formed by the surrounding region and the inner surface of the hole.

5. The ceramic structure according to claim 4, wherein
the base body further comprises an outer side region surrounding the surrounding region, and
the surrounding region is located higher than the outer side region and configures a recessed portion.

6. The ceramic structure according to claim 1, wherein
the terminal part comprises a terminal conductor which is at least partially located inside the base body and which is exposed from the lower surface of the base body to the exterior of the base body, and
the adjacent region is adjacent to the terminal conductor and surrounds the terminal conductor.

7. The ceramic structure according to claim 6, wherein
the terminal conductor comprises
a body portion which extends outward from an interior of the base body to the exterior of the base body, and
a reduced-diameter portion which is located inside the base body, has a smaller diameter than that of the body portion, and comprises an outer circumferential surface connected to the internal conductor.

8. The ceramic structure according to claim 6, further comprising:
an insulating lid body in which the terminal conductor is inserted and which covers the adjacent region from below; and
an insulating sealing material which is interposed between the adjacent region and the lid body and is adhered to the two.

9. The ceramic structure according to claim 1, wherein
the terminal part comprises:
an insulating portion which is at least partially located inside the base body and which is exposed from the lower surface of the base body to the exterior of the base body; and
a terminal conductor which is at least partially located inside the base body and which is exposed from a lower surface of the insulating portion to the exterior of the base body by passing through the insulating portion, and
the adjacent region is adjacent to the insulating portion and surrounds the insulating portion.

10. The ceramic structure according to claim 9, wherein
the insulating portion is made of ceramic, and
the base body and the insulating portion are fixed by adhesion of ceramic particles to each other.

11. The ceramic structure according to claim 1, wherein
the terminal parts comprises:
an insulating portion which is exposed from the lower surface of the base body to the exterior of the base body; and
a terminal conductor which is at least partially located inside the base body and which is exposed from a lower surface of the insulating portion to the exterior of the base body by passing through the insulating portion,
the adjacent region is adjacent to the insulating portion and surrounds the insulating portion, and
the insulating portion extends outward lower than the adjacent region.

12. The ceramic structure according to claim 9, wherein the terminal conductor passes through the insulating portion in a state where an outer circumferential surface of the terminal conductor is covered by the insulating portion over an entire circumference.

13. The ceramic structure according to claim 9, wherein the terminal conductor passes through the insulating portion in a state where a portion of an outer circumferential surface of the terminal conductor is exposed from an outer circumferential surface of the insulating portion.

14. The ceramic structure according to claim 9, wherein
a principal constituent of the base body and a principal constituent of the insulating portion are made of the same ceramics, and
the mean crystal grain size in the insulating portion is larger than the mean crystal grain size in the base body.

15. The ceramic structure according to claim 9, wherein
the terminal part further comprises a connection conductor which is located inside the base body and is connected to the internal conductor, and
the terminal conductor has a diameter smaller than that of the connection conductor when viewing the base body on a plane, is electrically connected through the connection conductor with the internal conductor, and at least partially is located lower than the connection conductor.

16. The ceramic structure according to claim 1, wherein
the terminal part further comprises:
a connection conductor which is at least partially located inside the base body and is connected to the internal conductor; and
a terminal conductors which has a diameter smaller than that of the connection conductor when viewing the base body on a plane, is electrically connected through the connection conductor with the internal conductor, and at least partially is located lower than the connection conductor, and
the adjacent region is adjacent to the connection conductor and surrounds the connection conductor.

17. The ceramic structure according to claim 15, wherein
the base body comprises a hole which is opened at the lower surface of the base body and in which the terminal part is inserted, and
the connection conductor comprises a recessed retracted portion in an outer circumferential surface surrounded by an inner surface of the hole.

18. The ceramic structure according to claim 17, wherein
the retracted portion extends so as to surround the connection conductor when viewing the base body on a plane, or
a plurality of the retracted portions are arranged so as to surround the connection conductor when viewing the base body on a plane.

19. A wafer system comprising:
a ceramic structure according to claim 1;
a power supply part which supplies power to the terminal part; and
a control part which controls the power supply part.
